(19) United States
(12) Patent Application Publication
(10) Pub. No.: US 2025/0254861 A1
(43) Pub. Date: Aug. 7, 2025

(54) SEMICONDUCTOR DEVICES

(71) Applicant: Samsung Electronics Co., Ltd., Suwon-si (KR)

(72) Inventors: Hyunjin Lee, Suwon-si (KR); Kiseok Lee, Suwon-si (KR); Donghyung Kim, Suwon-si (KR); Jongmin Kim, Suwon-si, Gyeonggi-do (KR); Yongkwan Kim, Suwon-si (KR); Huijung Kim, Suwon-si (KR)

(21) Appl. No.: 18/777,722

(22) Filed: Jul. 19, 2024

(30) Foreign Application Priority Data
Feb. 2, 2024 (KR) 10-2024-0016589

(51) Int. Cl. H10B 12/00

(52) U.S. Cl. CPC H10B 12/34; H10B 12/053; H10B 12/315

(57) ABSTRACT

A semiconductor device includes an active pattern on a substrate, the active pattern including a first tab, a second tab, and an active bar, a gate structure extending into the active bar of the active pattern in a first direction, a bit line structure on the first tab and extending in a second direction, a contact plug structure on the second tab of the active pattern, and a capacitor on the contact plug structure, where the active bar of the active pattern extends in a third direction that is substantially parallel to the upper surface of the substrate, defines an obtuse angle with respect to the first direction, and defines an acute angle with respect to the second direction.

### CROSS-REFERENCE TO RELATED APPLICATION

This application claims priority under 35 U.S.C. § 119 to Korean Patent Application No. 10-2024-0016589 filed on Feb. 2, 2024 in the Korean Intellectual Property Office, the disclosure of which is hereby incorporated by reference in its entirety.

### TECHNICAL FIELD

Example embodiments relate to a semiconductor device, and more particularly, a DRAM device.

### BACKGROUND

An active pattern of the DRAM device may include an active bar, and a first tab and a second tab respectively on opposite end portions of the active bar. A gate structure may extend in a first direction extending through the active bar of the active pattern, a bit line may be disposed on the first tab of the active pattern and may extend in a second direction, and a contact plug may be disposed on the second tab of the active pattern.

### SUMMARY

Example embodiments provide a semiconductor device having improved characteristics.

According to example embodiments, there is provided a semiconductor device. The semiconductor device may include an active pattern on a substrate, the active pattern including a first tab, a second tab, and an active bar between the first tab and the second tab, a gate structure extending into the active bar of the active pattern in a first direction that is substantially parallel to an upper surface of the substrate, a bit line structure on the first tab of the active pattern and extending in a second direction that is substantially parallel to the upper surface of the substrate and orthogonal to the first direction, a contact plug structure on the second tab of the active pattern, and a capacitor on the contact plug structure, where the active bar of the active pattern extends in a third direction, where the first tab and the second tab of the active pattern are respectively on a first end of the active bar and a second end of the active bar that is opposite to the first end in the third direction and extend from the active bar in the second direction, where the third direction is substantially parallel to the upper surface of the substrate, defines an obtuse angle with respect to the first direction, and defines an acute angle with respect to the second direction.

According to example embodiments, there is provided a semiconductor device. The semiconductor device may include a plurality of active patterns that are on a substrate and spaced apart in a first direction and a second direction that is orthogonal to the first direction, where each active pattern of the plurality of active patterns includes a first tab, a second tab spaced apart from the first tab in a third direction, and an active bar that is between the first tab and the second tab and extends in the third direction, where the third direction is substantially parallel to an upper surface of the substrate, defines an obtuse angle with respect to the first direction, and defines an acute angle with respect to the second direction, and where the first tab and the second tab of each of the plurality of active patterns extend in the second direction from the active bar.

According to example embodiments, there is provided a semiconductor device. The semiconductor device may include a plurality of active patterns that are on a substrate and spaced apart in a first direction and a second direction that is orthogonal to the first direction, where: each active pattern of the plurality of active patterns includes a first tab, a second tab spaced apart from the first tab in a third direction, and an active bar that is between the first tab and the second tab and extends in the third direction, the third direction is substantially parallel to an upper surface of the substrate, defines an obtuse angle with respect to the first direction, and defines an acute angle with respect to the second direction, the first tab and the second tab of each of the plurality of active patterns extend in the second direction from the active bar, a first set of the plurality of active patterns are spaced apart in the first direction, and a second set of the plurality of active patterns are spaced apart in the second direction, a gate structure extending into the active bars of the first set of the plurality of active patterns, a bit line structure extending into the first tabs of the second set of the plurality of active patterns, contact plug structures that are respectively on the second tabs of the plurality of active patterns, and capacitors that are respectively on the contact plug structures.

In the semiconductor device according to example embodiments, the active pattern may include the active bar, and the first and second tabs respectively disposed on opposite end portions of the active bar. The bit line may be disposed on the first tab of the active pattern, and the contact plug structure may be disposed on the second tab of the active pattern. Accordingly, the degree of integration of the semiconductor device may be improved.

### BRIEF DESCRIPTION OF THE DRAWINGS

FIGS. 1, 2 and 3 are plan and cross-sectional views illustrating an active pattern according to example embodiments.

FIGS. 4, 5, 6, 7, 8, and 9 are plan and cross-sectional views illustrating a method of manufacturing an active pattern according to example embodiments.

FIGS. 10, 11, 12, 13, 14, 15, 16, 17, and 18 illustrate various shapes of upper surfaces of active patterns according to example embodiments.

FIGS. 19, 20, and 21 are plan and cross-sectional views illustrating a semiconductor device according to example embodiments.

FIGS. 22, 23, 24, 25, 26, 27, 28, 29, 30, 31, 32, 33, 34, 35, 36, and 37 are plan and cross-sectional views illustrating a method of manufacturing a semiconductor device according to example embodiments.

FIGS. 38, 39, 40, 41, 42, 43, 44, 45, and 46 are plan and cross-sectional views illustrating a method of manufacturing a semiconductor device according to example embodiments.

FIGS. 47, 48, and 49 are plan and cross-sectional views illustrating a method of manufacturing a semiconductor device according to example embodiments.

FIG. 50 is a cross-sectional view illustrating a semiconductor device according to example embodiments.

FIG. 51 is a cross-sectional view illustrating a method of manufacturing a semiconductor device according to example embodiments.

FIGS. 52 and 53 are a plan view and a cross-sectional view illustrating a semiconductor device according to example embodiments.

FIG. 54 is a cross-sectional view illustrating a semiconductor device according to example embodiments.

FIG. 55 is a cross-sectional view illustrating a semiconductor device according to example embodiments.

FIG. 56 is a cross-sectional view illustrating a method of manufacturing a semiconductor device according to example embodiments.

FIG. 57 is a cross-sectional view illustrating a method of manufacturing a semiconductor device according to example embodiments.

### DETAILED DESCRIPTION

The above and other aspects and features of a semiconductor device, a method of manufacturing the same, and an electronic system including the same in accordance with example embodiments will become readily understood from detail descriptions that follow, with reference to the accompanying drawings. It will be understood that, although the terms “first,” “second,” and/or “third” may be used herein to describe various materials, levels (layers), regions, pads, electrodes, patterns, structures or processes should not be limited by these terms. These terms are only used to distinguish one material, level (layer), region, pad, electrode, pattern, structure or process from another material, level (layer), region, pad, electrode, pattern, structure or process. Thus, a first material, level (layer), region, pad, electrode, pattern, structure or process discussed below could be termed a second or third material, level (layer), region, pad, electrode, pattern, structure or process without departing from the teachings of the present disclosure.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection.

Hereinafter, two directions among horizontal directions that are substantially parallel to an upper surface of a substrate, which may be substantially orthogonal to each other, may be referred as first and second directions D1 and D2, respectively, a direction among the horizontal directions, which may have an obtuse angle with respect to the first direction D1 and an acute angle with respect to the second direction D2 may be referred to as a third direction D3, and a direction among the horizontal directions, which may have an acute angle with respect to the first and second directions D1 and D2 and be substantially orthogonal to the third direction D3 may be referred to as a fourth direction D4. Additionally, a direction substantially perpendicular to the upper surface of the substrate may be referred to as a vertical direction. Each of the first to fourth directions D1, D2, D3 and D4 and the vertical direction may represent not only a direction shown in the drawing, but also an opposite direction.

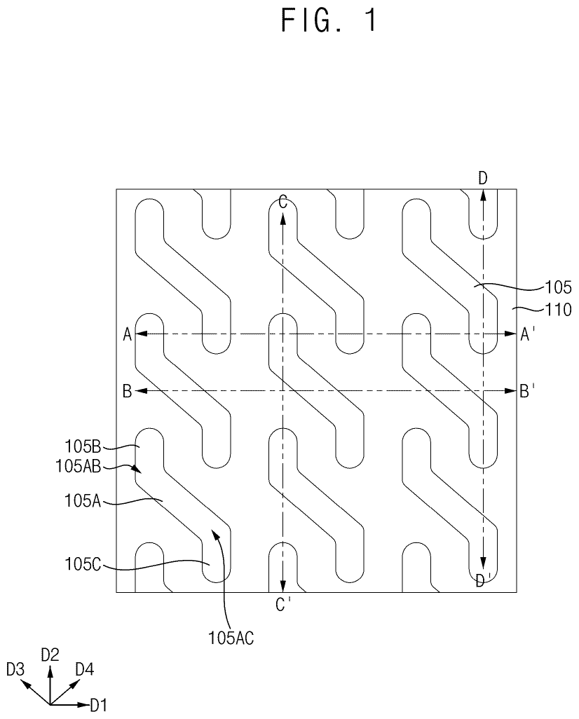

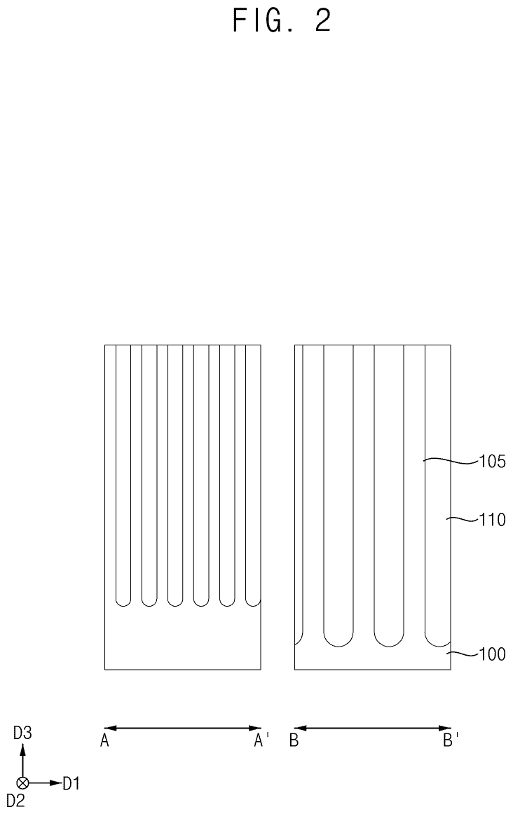

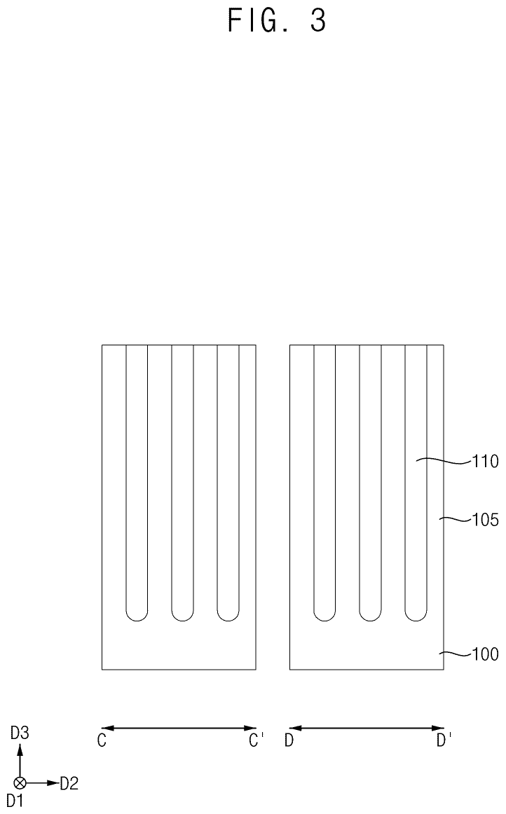

FIGS. 1 to 3 are a plan view and cross-sectional views illustrating an active pattern according to example embodiments. Specifically, FIG. 1 is the plan view, FIG. 2, includes cross-sectional views taken along lines A-A′ and B-B′ of FIG. 1, and FIG. 3 includes cross-sectional views taken along lines C-C′ and D-D′ of FIG. 1.

The substrate 100 may include silicon, germanium, silicon-germanium or a III-V group compound such as GaP, GaAs, GaSb, etc. In some embodiments, the substrate 100 may be a silicon-on-insulator (SOI) substrate or a germanium-on-insulator (GOI) substrate.

The active pattern 105 may include an active bar 105A, a first tab 105B, and a second tab 105C. The active bar 105A of the active pattern 105 may extend in the third direction D3 to a certain length. The first and second tabs 105B, 105C of the active pattern 105 may be formed at opposite end portions in the third direction D3 of the active bar 105A in, respectively, and may extend in the second direction D2 away from the active bar 105A to a certain length.

A plurality of active patterns 105 may be spaced apart from each other in the first and second directions D1 and D2, and accordingly, an active pattern array may be defined.

A plurality of active patterns 105 arranged along the first direction D1 of the active pattern array may define an active pattern row. A plurality of active pattern rows may be spaced apart from each other in the second direction D2. A plurality of active patterns 105 arranged along the second direction D2 of the active pattern array may define an active pattern column. A plurality of active pattern columns may be spaced apart from each other in the first direction D1. Accordingly, the active patterns 105 of the active pattern array may be arranged, for example, in a lattice pattern in a plan view.

In example embodiments, the active patterns 105 of each of the active pattern rows may be aligned with each other in the first direction D1. Specifically, the first tabs 105B of the active patterns 105 of the active pattern row may be arranged on a straight line extending in the first direction D1 to define a first tab row (e.g., a first set of active patterns 105), and the second tabs of the active patterns 105 of the active pattern row may be arranged on a straight line extending in the first direction D1 to define a second tab row (e.g., a second set of active patterns 105).

In example embodiments, the active patterns 105 of each of the active pattern columns may be aligned with each other in the second direction D2. Specifically, the first tabs 105B of the active patterns 105 of the active pattern column may be arranged on a straight line extending in the second direction D2 to define a first tab column, and the second tabs of the active patterns 105 of the active pattern column may be arranged on a straight line extending in the second direction D2 to define a second tab column.

The first tab 105B of the active pattern 105 of a first active pattern row of the active pattern rows may be disposed between the second tabs of the active patterns 105 adjacent to each other in the first direction D1 of a second active pattern row of the active pattern rows. The first and second active pattern rows may be adjacent to each other in the second direction D2. Accordingly, the first tabs 105B of the active patterns 105 included in the first active pattern row (e.g., the first set of active patterns) and the second tabs of the active patterns 105 included in the second active pattern row (e.g., the second set of active patterns) may be arranged alternately and repeatedly in the first direction D1 (e.g., the first tabs 105B the first set active patterns 105 and the second tabs 105C of the second set of active patterns 105 are alternately stacked in the first direction D1).

A sidewall of the active pattern 105 may be covered or overlapped by the isolation pattern 110. The active pattern 105 may include substantially the same material as the substrate 100, and the isolation pattern 110 may include an oxide, e.g., silicon oxide.

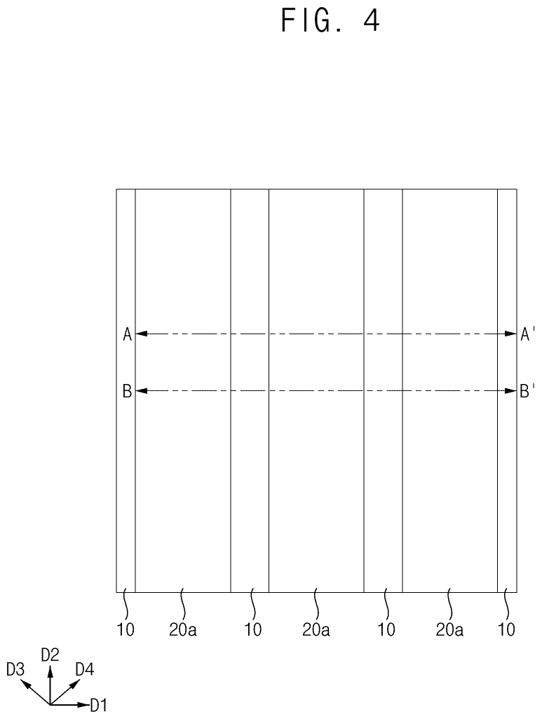

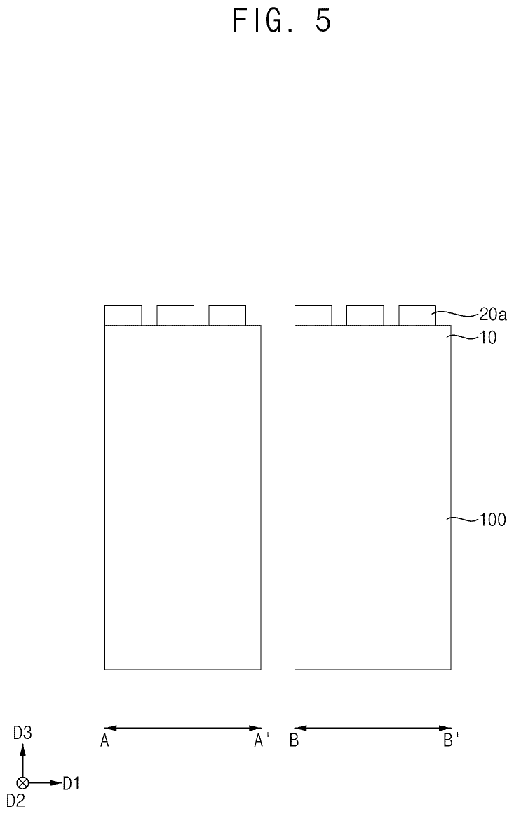

FIGS. 4 to 9 are plan views and cross-sectional views illustrating a method of manufacturing an active pattern according to example embodiments. Specifically, FIGS. 4, 6 and 8 are the plan views, and FIGS. 5, 7 and 9 include cross-sectional views taken along lines A-A′ and B-B′ of corresponding plan views.

Referring to FIGS. 4 and 5, a hard mask layer 10 and a first mask layer may be sequentially formed on the substrate 100 in the vertical direction.

In example embodiments, the hard mask layer 10 may include, for example, metal oxide, silicon oxide, silicon oxynitride, silicon nitride, etc. The first mask layer may include a material having a high etch selectivity with respect to the hard mask layer 10, for example, silicon.

The hard mask layer 10 is illustrated as a single layer, but the concept of the present disclosure is not limited thereto. That is, the hard mask layer 10 may include a plurality of layers each containing different materials.

A first patterning process may be performed on the first mask layer in a shape of a line extending in the second direction D2. Accordingly, the first mask layer may be divided into a plurality of preliminary first masks 20a each extending in the second direction D2 and spaced apart from each other in the first direction D1.

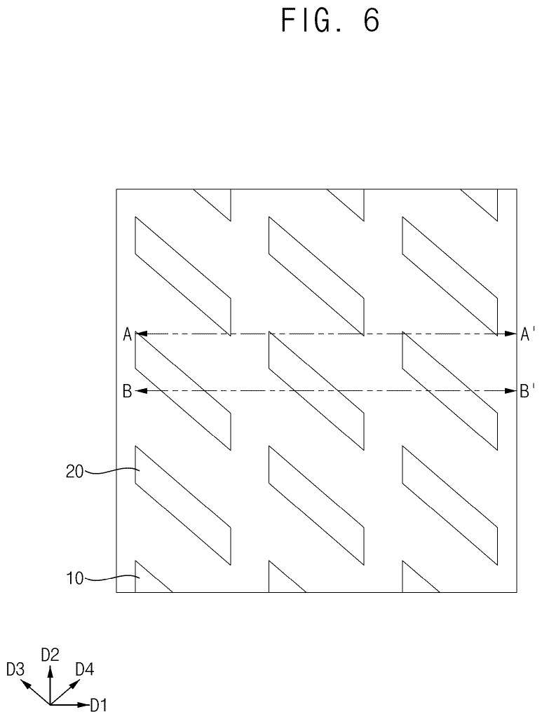

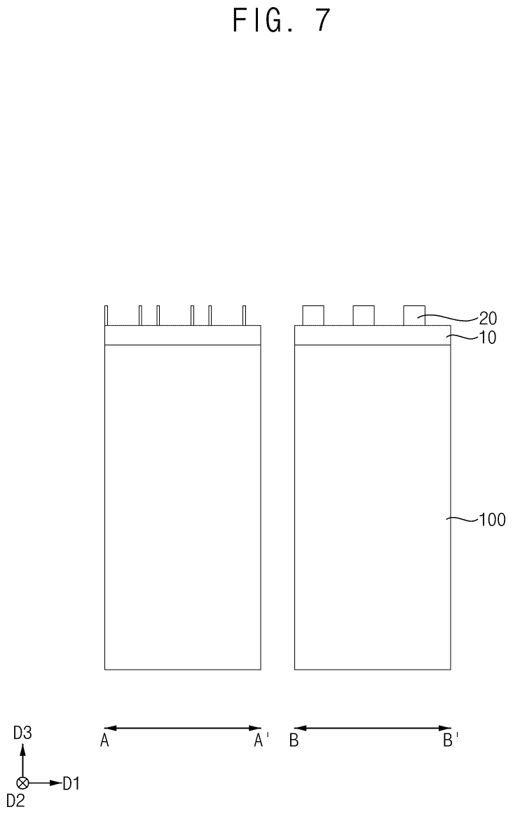

Referring to FIGS. 6 and 7, a second patterning process may be performed on the preliminary first masks 20a in a shape of a line extending in the third direction D3. Accordingly, each of the preliminary first masks 20a may be divided into a plurality of first masks 20 spaced apart from each other in the second direction D2.

Unlike the above-illustrated process sequence, the second patterning process performed in a shape of a line extending in the third direction D3 may be first performed, and the first patterning process performed in a line shape extending in the second direction D2 may be performed later to form the first mask 20.

The first mask 20 may be formed at a position corresponding to the active bar 105A of the active pattern 105.

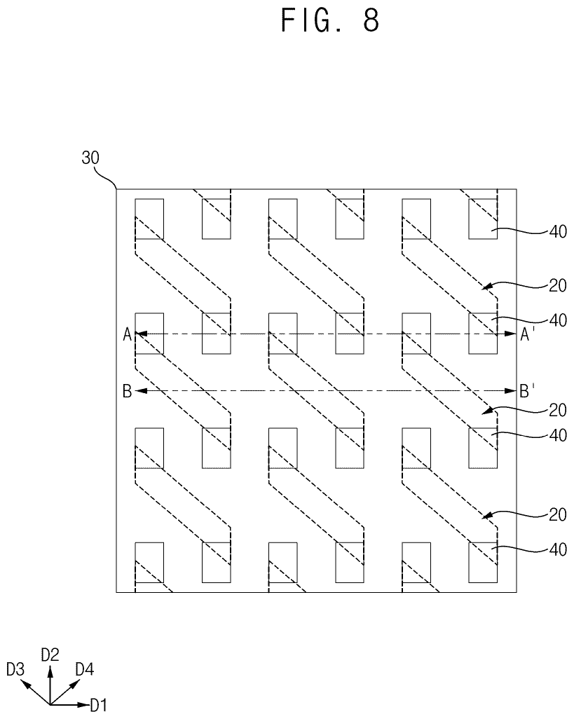

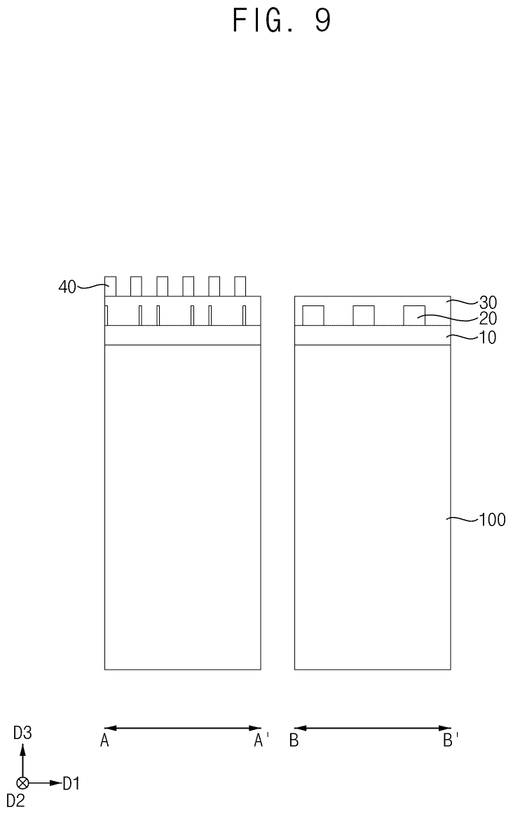

Referring to FIGS. 8 and 9, a first mold layer 30 and a second mask layer may be sequentially formed on the hard mask layer 10 and the first mask 20 in the vertical direction.

The second mask layer is illustrated as a single layer, but the concept of the present disclosure is not limited thereto. That is, the second mask layer may include a plurality of layers each containing different materials.

In example embodiments, the first mold layer 30 may include, for example, a carbon-containing layer such as Spin On Hardmask (SOH), silicon oxide, silicon oxynitride, silicon nitride, etc. The second mask layer may include a material having a high etch selectivity with respect to the first mold layer 30 and the hard mask layer 10, for example, silicon, but is not limited thereto.

A patterning process may be performed on the second mask layer to divide the second mask layer into a plurality of second masks 40 spaced apart from each other in each of the first and second directions D1 and D2. The second mask 40 may overlap in the vertical direction and an end portion in the third direction of the first mask 20. Accordingly, the second mask 40 may be arranged, for example, in a lattice pattern in a plan view.

The second mask 40 may be formed at a position corresponding to the first tab 105B or the second tab of the active pattern 105.

An upper surface of the second mask 40 is illustrated to have a shape of a rectangle having two sides facing in the first direction D1 and two sides facing in the second direction D2, but the concept of the present disclosure is not limited thereto. That is, the upper surface of the second mask 40 may have a shape of a rhombus in plan view having two sides facing each other in the third direction D3 and two sides facing each other in the fourth direction D4.

In example embodiments, the second mask 40 may be formed by a third patterning process performed in a shape of a line extending in the first direction D1 and a fourth patterning process performed in a shape of a line extending in the second direction D2, and the order of the third and fourth patterning processes is not limited thereto.

Process sequence of the first mask 20 and the second mask 40 is not limited. That is, the first mask 20 may be formed after the second mask 40. As illustrated below, a shape of an upper surface of the active pattern 105 may vary depending on stacking order of the first and second masks 20 and 40.

Referring to FIGS. 1 to 3 again, a patterning process using the first and second masks 20 and 40 as an etching mask may be performed to divide the hard mask layer 10 into a plurality of hard masks spaced apart from each other in each of the first and second directions D1 and D2. Thereafter, the first and second masks 20 and 40 and the first mold layer 30 may be removed.

An etching process using the hard mask may be performed on an upper portion of the substrate 100 to form a first recess. An active pattern 105 may be defined on the substrate 100 by the first recess. Afterwards, an isolation pattern 110 may be formed to fill or be in the first recess.

The active pattern 105 may be formed to include an active bar 105A corresponding to the first mask 20 and a first tab 105B and a second tab each corresponding to the second mask 40.

In example embodiments, a plurality of active patterns 105 may be spaced apart from each other in the first and second directions D1 and D2, respectively, and accordingly, an active pattern array may be defined. The active patterns 105 arranged along the first direction D1 of the active pattern array may define an active pattern row. A plurality of active pattern rows may be spaced apart from each other in the second direction D2. The active patterns 105 arranged along the second direction D2 of the active pattern array may define an active pattern column. A plurality of active pattern columns may be spaced apart from each other in the first direction D1.

The first tabs 105B of the active patterns 105 of the active pattern row may define a first tab row. The second tabs of the active patterns 105 of the active pattern row may define a second tab row. The first tabs 105B of the active patterns 105 of the active pattern column may define a first tab column. The second tabs of the active patterns 105 of the active pattern column may define a second tab column.

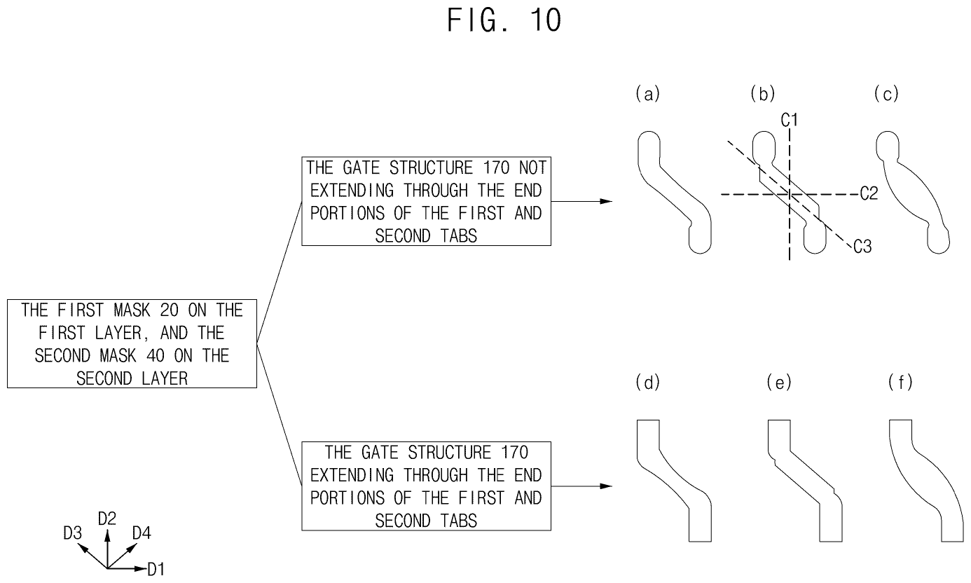

FIGS. 10 to 18 illustrate various shapes of upper surfaces of the active patterns 105 according to example embodiments.

FIGS. 10 to 15 illustrate cases in which the upper surface of the second mask 40 has a shape of a rectangle in plan view having two sides facing each other in the first direction D1 and two sides facing each other in the second direction D2.

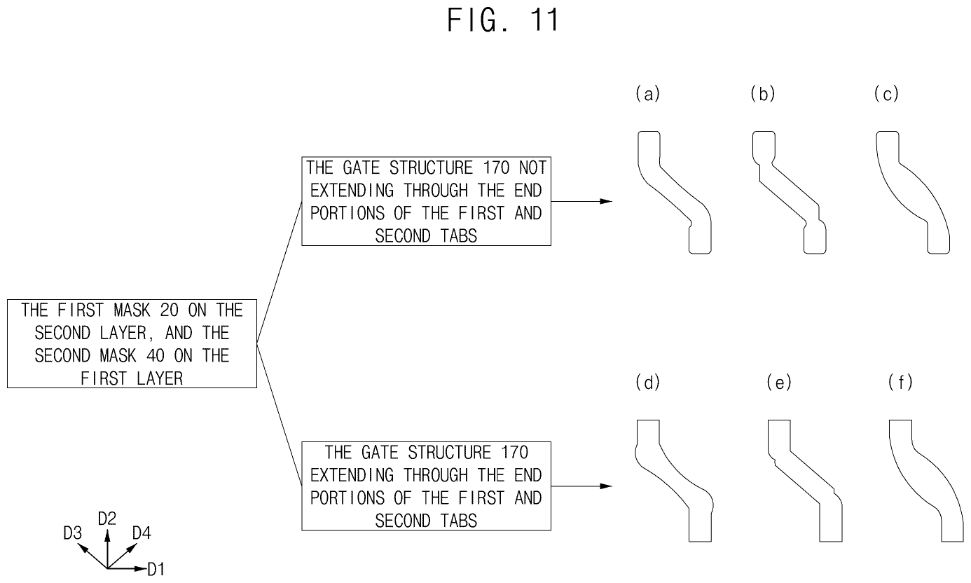

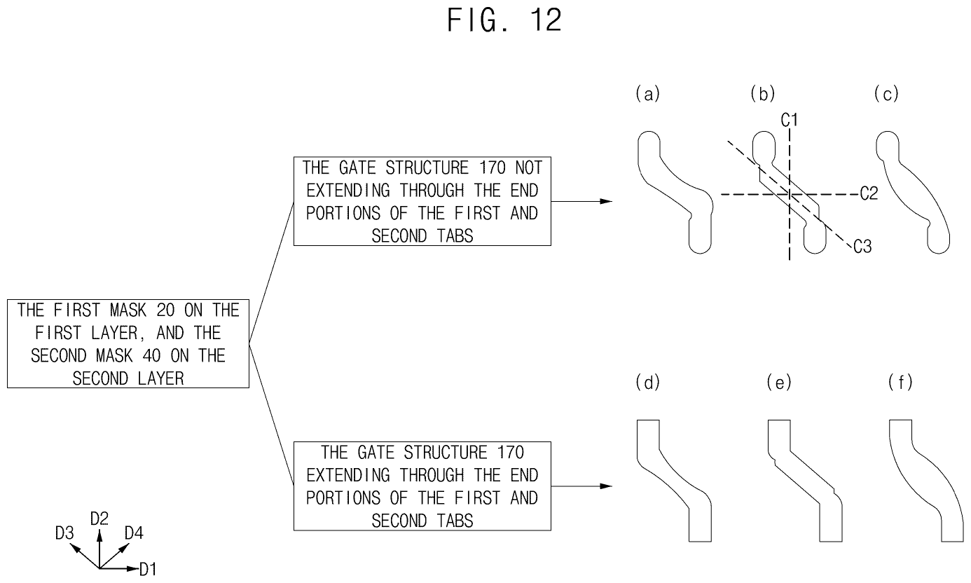

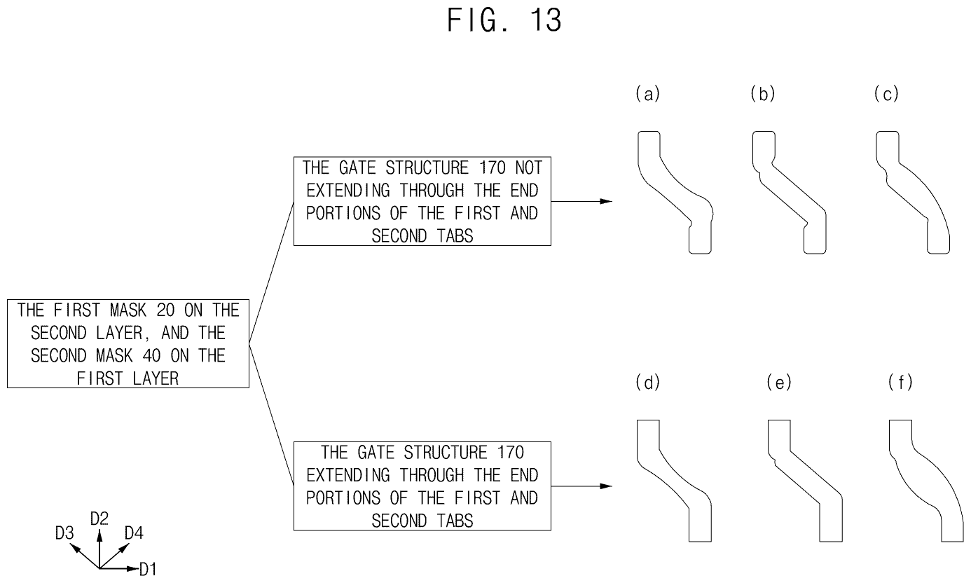

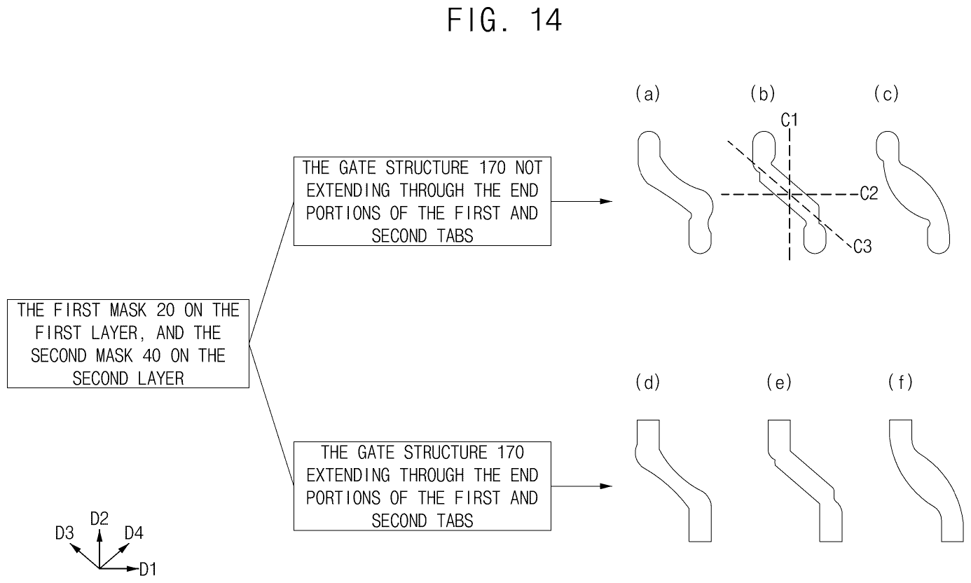

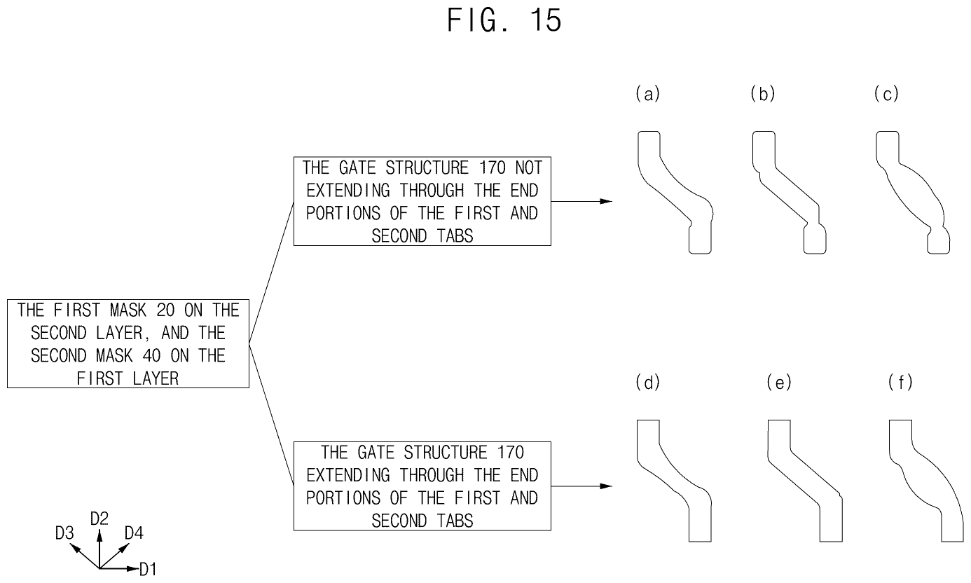

FIGS. 10 and 11 illustrate cases in which the first and second masks 20 and 40 are properly aligned in each of the first and second directions D1 and D2, FIGS. 12 and 13 illustrates cases in which the first and second masks 20 and 40 are misaligned in the first direction D1, and FIGS. 14 and 15 illustrate cases in which the first and second masks 20 and 40 are misaligned in the second direction D2.

Hereinafter, an imaginary straight line extending in the second direction D2 through the center of gravity of the active bar 105A is referred to as a first center line C1, an imaginary straight line extending in the first direction D1 through the center of gravity of the active bar 105A is referred to as a second center line C2, and an imaginary straight line extending in the third direction D3 through the center of gravity of the active bar 105A is referred to as a third center line C3.

Referring to FIGS. 10 and 11, when the first and second masks 20 and 40 are properly aligned in the first and second directions D1 and D2, a first vertical distance in the first direction D1 from a side of the first tab 105B to the first center line C1, and a second vertical distance in the first direction D1 from a side of the second tab 105C to the first center line C1 may be substantially the same to each other. Also, a third vertical distance in the second direction D2 from a side of the first tab 105B to the second center line C2, and a fourth vertical distance in the second direction D2 from a side of the second tab 105C to the second center line C2 may be substantially the same to each other.

In example embodiments, a first width of a first neck 105AB where the active bar 105A and the first tab 105B meet (e.g., a first interface of the first tab 105B and the active bar 105A), and a second width of a second neck 105AC where the active bar 105A and the second tab 105C meet (e.g., a second interface of the second tab 105C and the active bar 105A) may be substantially the same.

In example embodiments, the shape of the active pattern 105 may be point symmetrical with respect to the center of gravity of the active bar 105A.

Referring to FIGS. 12 and 13, the third vertical distance and the fourth vertical distance may be substantially the same. However, the first mask 20 and the second mask 40 may be misaligned in the first direction D1, and thus, the first vertical distance and the second vertical distance may be different from each other. As illustrated, the first vertical distance may be greater than the second vertical distance, but the concept of the present disclosure is not limited thereto. That is, the second vertical distance may be greater than the first vertical distance.

In example embodiments, the first width of the first neck 105AB and the second width of the second neck 105AC may be different from each other. As illustrated, the second width may be greater than the first width, but the concept of the present disclosure is not limited thereto. That is, the first width may be greater than the second width.

Referring to FIGS. 14 and 15, the first vertical distance and the second vertical distance may be substantially the same. However, the first mask 20 and the second mask 40 may be misaligned in the second direction D2, and thus, the third vertical distance and the fourth vertical distance may be different from each other. As illustrated, the fourth vertical distance may be greater than the third vertical distance, but the concept of the present disclosure is not limited thereto. That is, the third vertical distance may be greater than the fourth vertical distance.

In example embodiments, the first width of the first neck 105AB and the second width of the second neck 105AC may be different from each other. As illustrated, the first width may be greater than the second width, but the concept of the present disclosure is not limited thereto. That is, the second width may be greater than the first width.

Referring to (a) to (c) included in each of FIGS. 10, 12 and 14, when the first mask 20 is formed first and the second mask 40 is formed later, each of upper surfaces of the first and second tab 105B, 105C may have a shape similar to a semi-oval in a plan view.

Referring to (a) to (c) included in each of FIGS. 11, 13 and 15, unlike the processes illustrated with reference to FIGS. 4 to 9, when the second mask 40 is formed first and the first mask 20 is formed later, each of the upper surfaces of the first and second tabs 105B, 105C may have a shape similar to a rectangle with rounded vertices rather than a semi-oval.

That is, as the second mask 40 moves away from the substrate 100, which is the final etch target layer, the upper surfaces of the first and second tabs 105B, 105C may have rounder vertices than that of the upper surface of the second mask 40.

Referring to (d) to (f) included in each of FIGS. 10 to 15, when sizes of the first and second tabs 105B, 105C are sufficiently large, or a width in the second direction D2 of a gate structure 170 is sufficiently large, the gate structure 170 may partially extend through or into end portions in the second direction D2 and away from the active bar 105A of the first and second tabs 105B, 105C. Accordingly, the upper surfaces of the first and second tabs 105B, 105C of the active pattern 105 may have a shape of a rectangle wherein a side thereof furthest from the active bar 105A may be angular rather than being rounded.

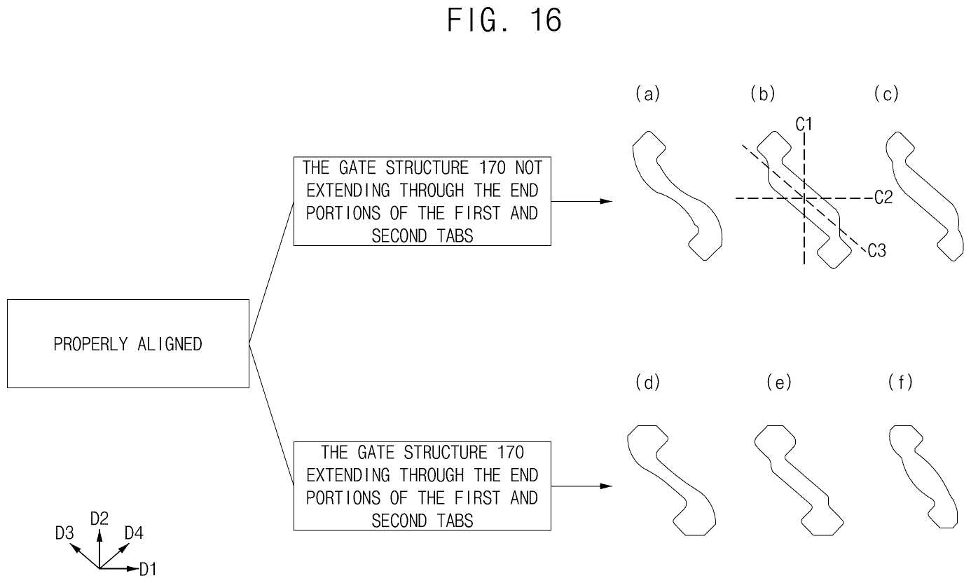

FIGS. 16 to 18 illustrate cases in which the upper surface of the second mask 40 has a shape of a rhombus having two sides facing each other in the third direction D3 and two sides facing each other in the fourth direction D4.

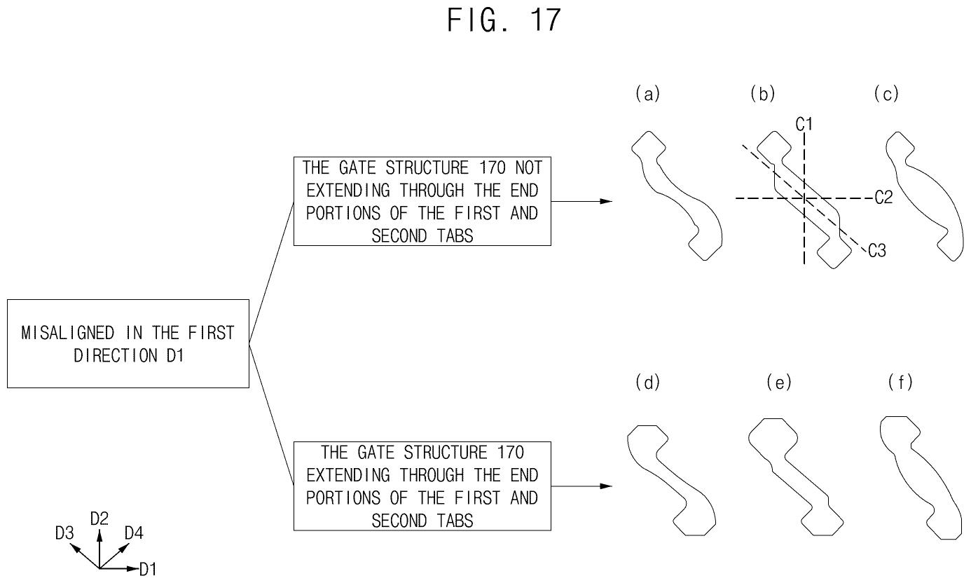

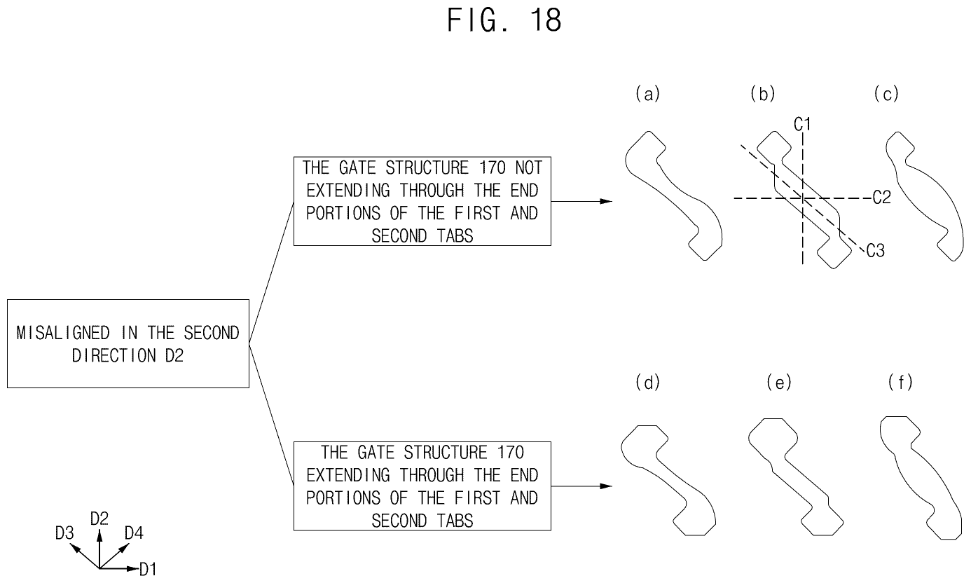

FIG. 16 illustrates cases in which the first and second masks 20 and 40 are properly aligned in the first and second directions D1 and D2, FIG. 17 illustrates cases in which the first and second masks 20 and 40 are misaligned in the first direction D1, and FIG. 18 illustrates cases in which the first and second masks 20 and 40 are misaligned in the second direction D2.

Referring to FIGS. 16, when the first and second masks 20 and 40 are properly aligned in the first and second directions D1 and D2, the first vertical distance and the second vertical distance may be substantially the same to each other. Also, the third vertical distance and the fourth vertical distance may be substantially the same to each other.

In example embodiments, the first width of the first neck 105AB and the second width of the second neck 105AC may be substantially the same.

In example embodiments, the shape of the active pattern 105 may be point symmetrical with respect to the center of gravity of the active bar 105A.

Referring to FIG. 17, the third vertical distance and the fourth vertical distance may be substantially the same. However, the first mask 20 and the second mask 40 may be misaligned in the first direction D1, and thus, the first vertical distance and the second vertical distance may be different from each other. As illustrated, the first vertical distance may be greater than the second vertical distance, but the concept of the present disclosure is not limited thereto. That is, the second vertical distance may be greater than the first vertical distance.

In example embodiments, the first width of the first neck 105AB and the second width of the second neck 105AC may be different from each other. As illustrated, the second width may be greater than the first width, but the concept of the present disclosure is not limited thereto. That is, the first width may be greater than the second width.

Referring to FIG. 18, the first vertical distance and the second vertical distance may be substantially the same. However, the first mask 20 and the second mask 40 may be misaligned in the second direction D2, and thus, the third vertical distance and the fourth vertical distance may be different from each other. As illustrated, the fourth vertical distance may be greater than the third vertical distance, but the concept of the present disclosure is not limited thereto. That is, the third vertical distance may be greater than the fourth vertical distance.

In example embodiments, the first width of the first neck 105AB and the second width of the second neck 105AC may be different from each other. As illustrated, the first width may be greater than the second width, but the concept of the present disclosure is not limited thereto. That is, the second width may be greater than the first width.

Referring to (a) to (c) included in each of FIGS. 16 to 18, each of upper surfaces of the first and second tab 105B, 105C may have a shape similar to rhombus with rounded vertices.

Referring to (d) to (f) included in each of FIGS. 16 to 18, when the sizes of the first and second tabs 105B, 105C are sufficiently large or the width in the second direction D2 of the gate structure 170 is sufficiently large, the gate structure 170 may partially extend through or into the end portions in the second direction D2 and away from the active bar 105A of the first and second tabs 105B, 105C. The upper surfaces of the first and second tabs 105B, 105C of the active pattern 105 may have a shape of a pentagon in plan view where a side thereof furthest from the active bar 105A may be angular rather than being rounded.

Referring to (a) and (d) included in each of FIGS. 10 to 18, a width in the fourth direction D4 of the upper surface of the active bar 105A may have a minimum value at a center portion in the third direction D3, and may increase towards each opposite end portions of the active bar 105A in the third direction D3. Two sides facing in the fourth direction D4 of the upper surface of the active bar 105A may have a concave curved shape with respect to the third center line C3.

Referring to (b) and (e) included in each of FIGS. 10 to 18, the width in the fourth direction D4 of the upper surface of the active bar 105A may be substantially constant in the third direction D3. The two sides facing in the fourth direction D4 of the upper surface of the active bar 105A may be substantially parallel to the third center line C3.

Referring to (c) and (f) included in each of FIGS. 10 to 18, the width in the fourth direction D4 of the upper surface of the active bar 105A may have a maximum value at a center portion in the third direction D3, and may decrease towards each opposite end portions of the active bar 105A in the third direction D3. The two sides facing in the fourth direction D4 of the upper surface of the active bar 105A may have a convex curved shape with respect to the third center line C3.

The width in the fourth direction D4 of the upper surface of the active bar 105A may be determined by a spacer additionally formed on a sidewall of the hard mask during the patterning process illustrated with reference to FIG. 1, or conditions of the patterning process such as temperature, time, etc.

Referring to (d) included in each of FIGS. 10 to 16, when the sizes of the first and second tabs 105B, 105C are relatively large, and the width in the fourth direction D4 of the upper surface of the active bar 105A increases toward the end portions in the third direction D3, the first width of the first neck 105AB and the second width of the second neck 105AC may be greater than that of other portions of the active pattern 105. That is, the width of the upper surface of the active pattern 105 may increase near the first and second necks 105AB, 105AC.

Referring to (b), (c), (e) and (f) included in each of FIGS. 10 to 18, when the width in the fourth direction D4 of the upper surface of the active bar 105A is constant along the third direction D3 (such as (b) or (e) included in each of FIGS. 10 to 18) or the width in the fourth direction D4 of the upper surface of the active bar 105A decreases towards each of the opposite end portions of the active bar 105A in the third direction D3 (such as (c) or (f) included in each of FIGS. 10 to 18), the first width of the first neck 105AB and the second width of the second neck 105AC may be relatively smaller than that of the other portions of the active pattern 105. That is, the width of the upper surface of the active pattern 105 may decrease near the first and second necks 105AB, 105AC.

That is, the first width of the first neck 105AB, where the active bar 105A and the first tab 105B meet, and the second width of the second neck 105AC, where the active bar 105A and the second tab 105C meet, may be greater or smaller than a width in the first direction D1 of the upper surfaces of the first and second tabs 105B, 105C or the width in the fourth direction D4 of the upper surface of the active bar 105A, depending on the sizes of the first and second tabs 105B, 105C and the width in the fourth direction D4 of the upper surface of the active bar 105A.

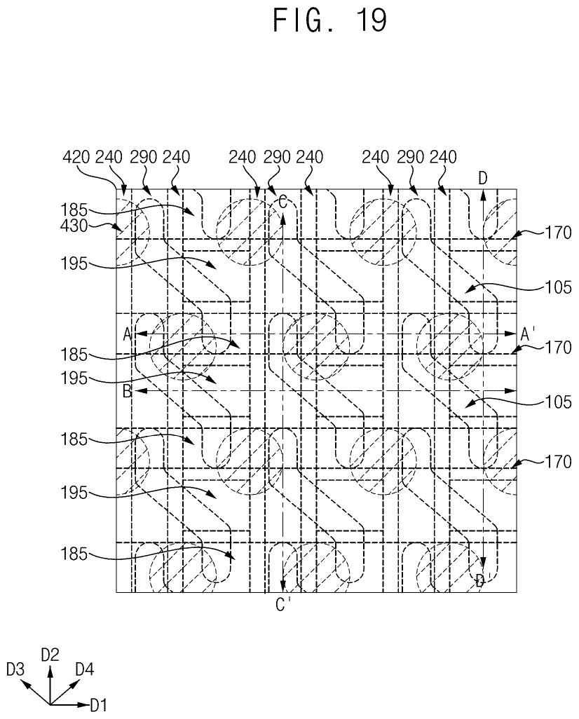

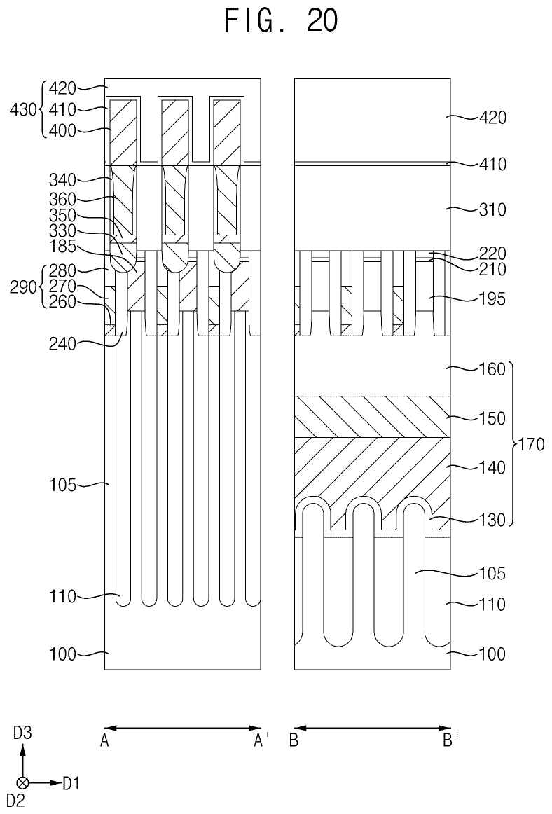

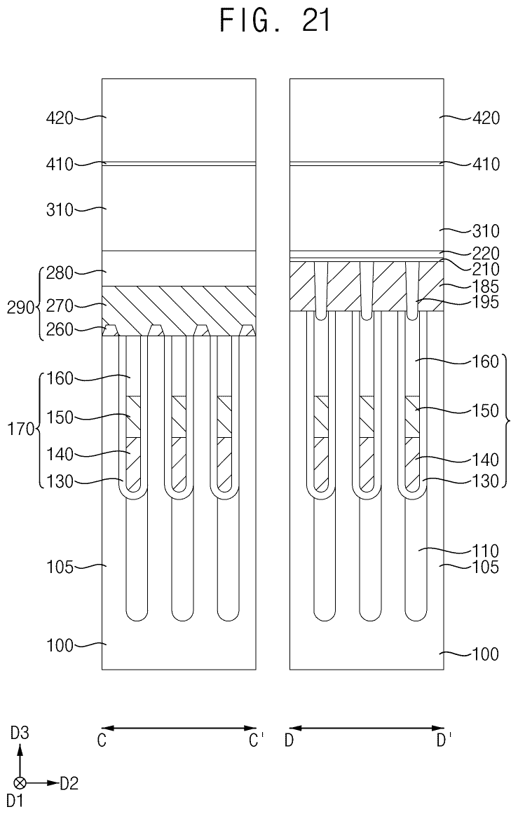

FIGS. 19 to 21 are a plan view and cross-sectional views illustrating a semiconductor device according to example embodiments. Specifically, FIG. 19 is the plan view, FIG. 20, includes cross-sectional views taken along lines A-A′ and B-B′ of FIG. 19, and FIG. 21 includes cross-sectional views taken along lines C-C′ and D-D′ of FIG. 19.

The semiconductor device applies the active pattern 105 illustrated with reference to FIGS. 1 to 3 to a DRAM device, and thus, repeated explanations of the active pattern 105 are omitted herein. The active pattern 105 may have shapes of the upper surfaces of the active patterns 105 illustrated with reference to FIGS. 1 to 3 as well as the active patterns 105 illustrated with reference to FIGS. 10 to 18.

Referring to FIGS. 1 to 3, the semiconductor device may include an active pattern 105, a gate structure 170, a bit line structure, a first contact plug 185, a contact plug structure and a capacitor 430 on a substrate 100.

The semiconductor device may further include an isolation pattern 110, a buffer layer structure, a second mold layer 310 and a second spacer 340.

The substrate 100 may include silicon, germanium, silicon-germanium or a III-V group compound such as GaP, GaAs, GaSb, etc. In some embodiments, the substrate 100 may be a silicon-on-insulator (SOI) substrate or a germanium-on-insulator (GOI) substrate.

The active pattern 105 may be defined on the substrate 100, and a sidewall of the active pattern 105 may be covered or overlapped by the isolation pattern 110. The active pattern 105 may include substantially the same material as the substrate 100, and the isolation pattern 110 may include an oxide, e.g., silicon oxide.

The gate structure 170 may extend in the first direction D1 through upper portions of the active bars 105A of the active patterns 105 of a corresponding active pattern row and an upper portion of the isolation pattern 110,

In example embodiments, a plurality of gate structures 170 may be spaced apart from each other in the second direction D2.

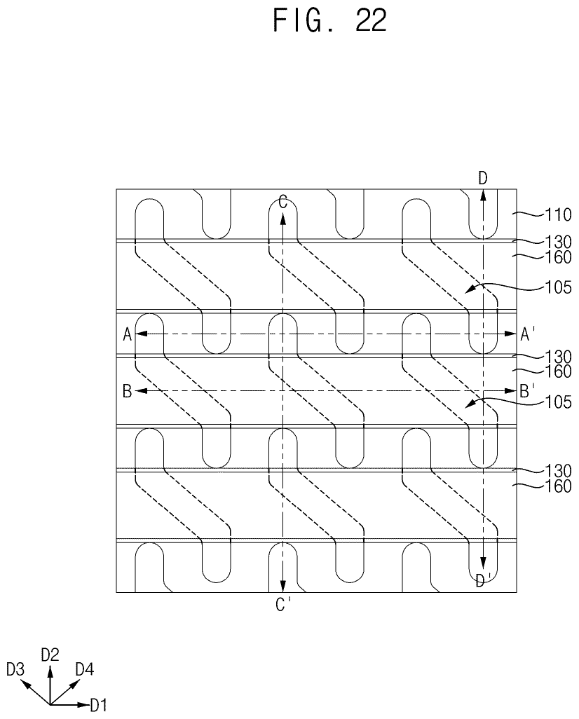

Referring to FIGS. 1 to 3 together with FIGS. 22, the gate structure 170 may extend in the first direction D1 through the upper portions of the active bars 105A of the active patterns 105 included in the corresponding active pattern row. However, the gate structure 170 may not extend through or into end portions in the second direction D2 of the first tabs 105B (or the second tabs) of the active patterns 105 included in a neighboring active pattern row, but the concept of the present disclosure is not limited thereto.

That is, if the first and second tabs 105B, 105C are sufficiently large, or if the width in the second direction D2 of the gate structure 170 is sufficiently large, the gate structure 170 may extend through or into, for example, not only the upper portions of the active bars 105A of the active patterns 105 included in the corresponding active pattern row, but also the end portions in the second direction D2 of the first tabs 105B (or the second tabs) of the active patterns 105 included in the neighboring active pattern row. In this case, the upper surfaces of the first and second tabs 105B, 105C of the active pattern 105 may have a side in the second direction D2 furthest from the active bar 105A that may be angular rather than being rounded such as (d) to (f) of FIGS. 10 to 18.

The gate structure 170 may include a first conductive pattern 140, a second conductive pattern 150 and a gate mask 160 sequentially stacked in the vertical direction and may further include a gate insulation pattern 130 covering or overlapping sidewalls of the first conductive pattern 140, the second conductive pattern 150 and the gate mask 160 and a lower surface of the first conductive pattern 140.

The gate insulation pattern 130 may include, for example, an oxide such as silicon oxide, the first conductive pattern 140 may include, for example, a metal, a metal nitride, a metal silicide, the second conductive pattern 150 may include, for example, polysilicon doped with n-type impurities or p-type impurities, and the gate mask 160 may include, for example, an insulating nitride such as silicon nitride.

The bit line structure may include a bit line 290 and first spacers 240 at opposite sidewalls of the bit line 290. The bit line structure may extend in the second direction D2, and a plurality of bit line structures may be spaced apart from each other in the first direction D1.

The bit line 290 may extend through or into upper portions of the first tabs 105B of the active patterns 105 included in the active pattern column, an upper portion of the isolation pattern 110 and an upper portion of the gate structure 170.

In example embodiments, the bit line 290 may extend in the second direction D2, and a plurality of bit lines 290 may be spaced apart from each other in the first direction D1.

The bit line 290 may include a first ohmic contact pattern 260, a third conductive pattern 270 and a bit line mask 280 sequentially stacked in the vertical direction. In example embodiments, a plurality of first ohmic contact patterns 260 may be respectively disposed on the first tabs 105B of the active patterns 105 included in the active pattern column to be spaced apart from each other in the second direction D2.

The first ohmic contact pattern 260 may include, for example, a metal silicide, and the third conductive pattern 270 may include, for example, a metal such as molybdenum, and the bit line mask 280 may include, for example, silicon oxide, silicon oxycarbide, etc.

In example embodiments, the bit line 290 may extend through or into an upper portion of the first tab 105B of the active pattern 105. Accordingly, the upper surface of the first tab 105B of the active pattern 105 may be lower than the upper surface of the second tab 105C of the active pattern 105.

In example embodiments, the first spacer 240 may include, for example, a low dielectric material such as silicon oxide, silicon oxycarbide, etc.

The first spacer 240 is illustrated as a single layer, but the concept of the present disclosure is not limited thereto. That is, the first spacer 240 may include a plurality of layers each containing different materials.

The first contact plug 185 may be formed on the second tab 105C of the active pattern 105. In example embodiments, a plurality of first contact plugs 185 may be spaced apart from each other in the second direction D2 between the bit line structures, and the fence pattern 195 may be formed between the first contact plugs 185 adjacent to each other in the second direction D2.

In example embodiments, the first contact plug 185 may include, for example, polysilicon doped with impurities, and the fence pattern 195 may include, for example, insulating nitride such as silicon nitride.

The buffer layer structure may include first and second buffer layers 210 and 220 sequentially stacked in the vertical direction on the first contact plug 185 and the fence pattern 195. The first buffer layer 210 may include, for example, a low dielectric material such as silicon oxide, silicon oxycarbide, etc., and the second buffer layer 220 may include, for example, a low dielectric material such as silicon nitride, silicon oxycarbonitride, etc.

In example embodiments, the buffer layer structure may extend in the second direction D2 on the first contact plugs 185 and the fence patterns 195 alternately and repeatedly arranged in the second direction D2, and a plurality of buffer layer structures may be spaced apart from each other in the first direction D1.

The second mold layer 310 may be formed on the buffer layer structure and the bit line structure. The second mold layer 310 may include, for example, a low dielectric material such as silicon oxide or silicon oxycarbide.

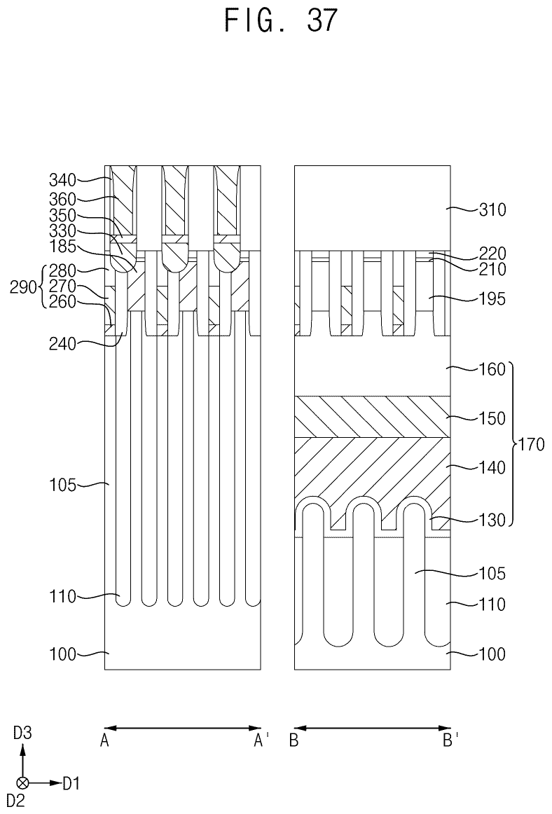

Referring to FIGS. 1 to 3 together with FIG. 37, the contact plug structure may include a second contact plug 330, a second ohmic contact pattern 350 and a third contact plug 360 sequentially stacked in the vertical direction on a bottom of a third opening 320 that may extend through or into the second mold layer 310, the bit line structure, the buffer layer structure and an upper portion of the first contact plug 185.

In example embodiments, a plurality of contact plug structures may be spaced apart from each other in each of the first and second directions D1 and D2, and may be arranged in a honeycomb pattern in a plan view. Each of the contact plug structures may have shape of, for example, a circle, an ellipse, a polygon, etc., in a plan view.

In example embodiments, the second contact plug 330 may include, for example, polysilicon doped with impurities, the second ohmic contact pattern 350 may include, for example, a metal silicide such as titanium silicide, cobalt silicide, nickel silicide, and the third contact plug 360 may include, for example, a metal such as tungsten.

The second spacer 340 may be formed between the second mold layer 310 and the third contact plug 360. The second spacer 340 may include, for example, a low dielectric material such as silicon nitride, silicon oxycarbonitride.

The capacitor 430 may include a lower electrode 400, a dielectric layer 410 and an upper electrode 420 sequentially stacked, and the lower electrode 400 may contact an upper surface of the third contact plug 360. Each of the lower and upper electrodes 410 and 420 may include, for example, a metal, a metal nitride, a metal silicide, silicon-germanium doped with impurities, etc., and the dielectric layer 410 may include, for example, a metal oxide with a high dielectric constant.

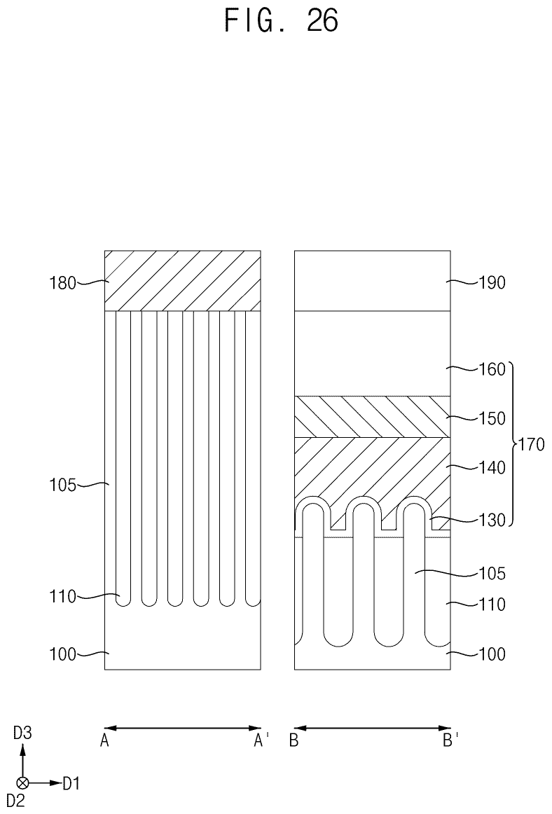

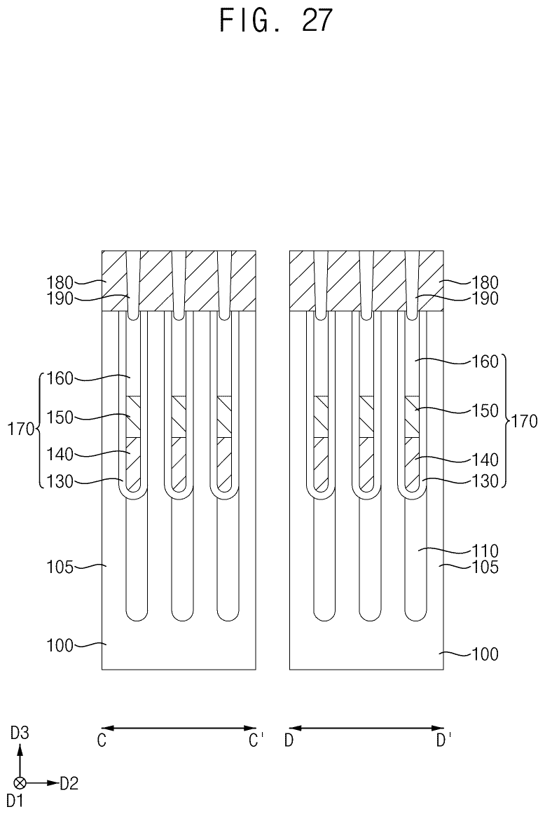

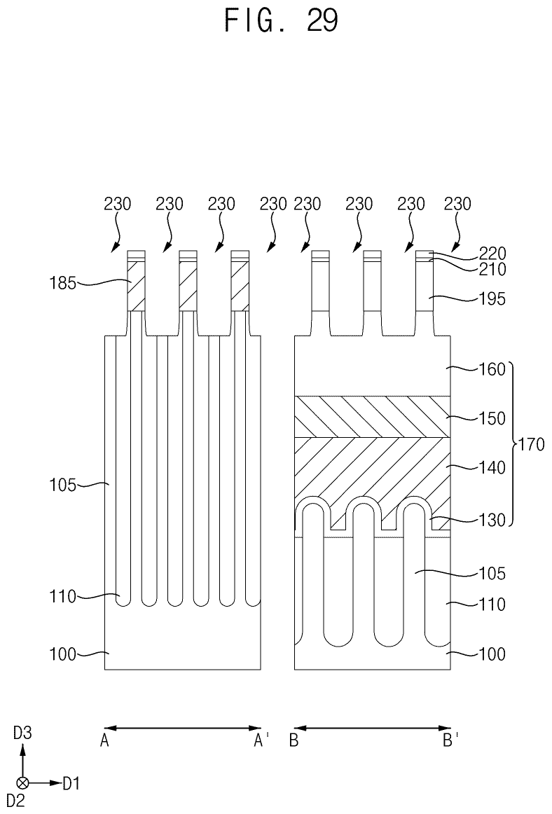

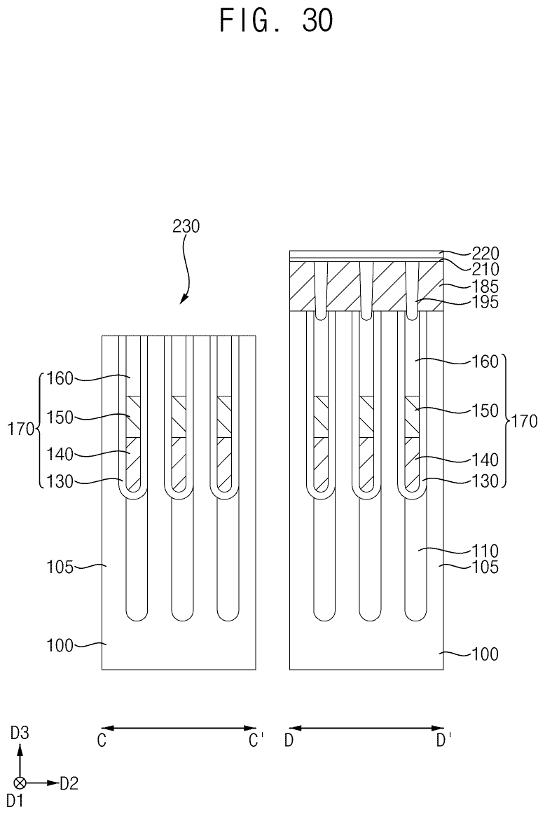

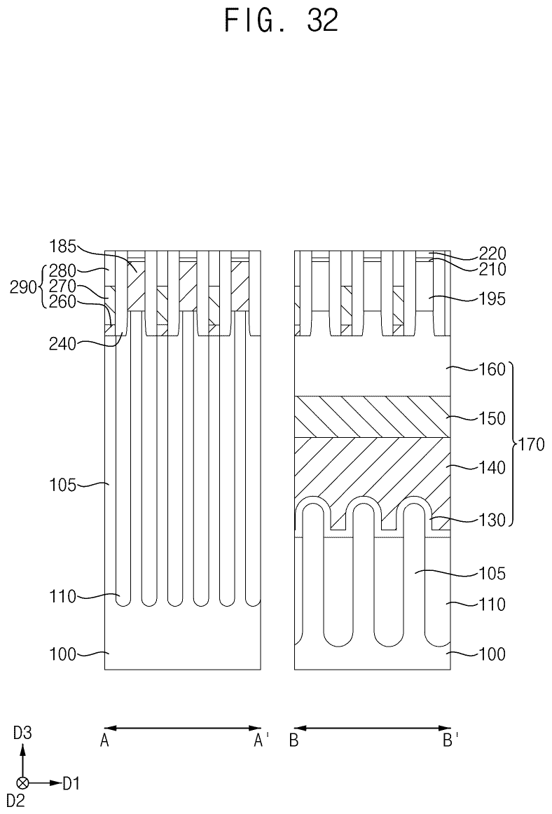

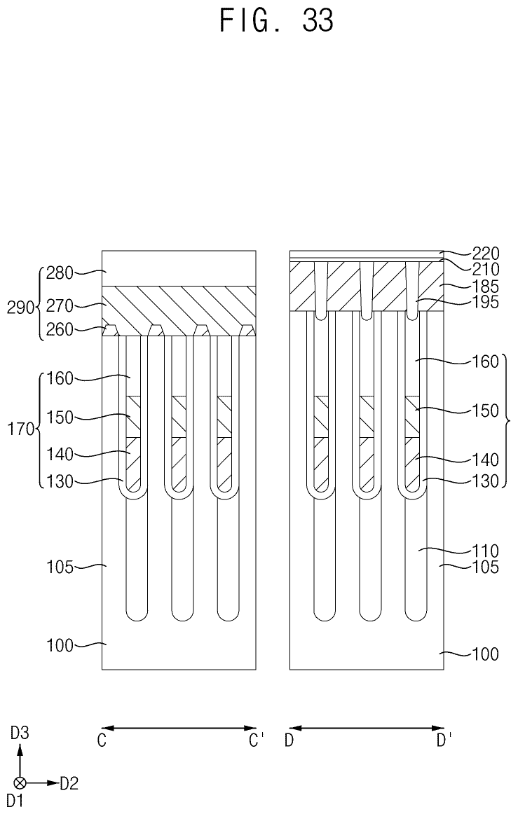

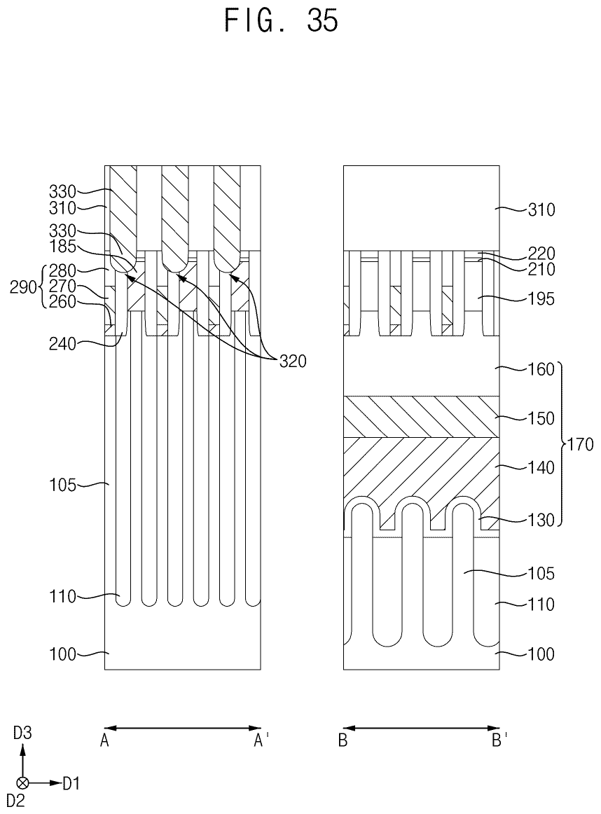

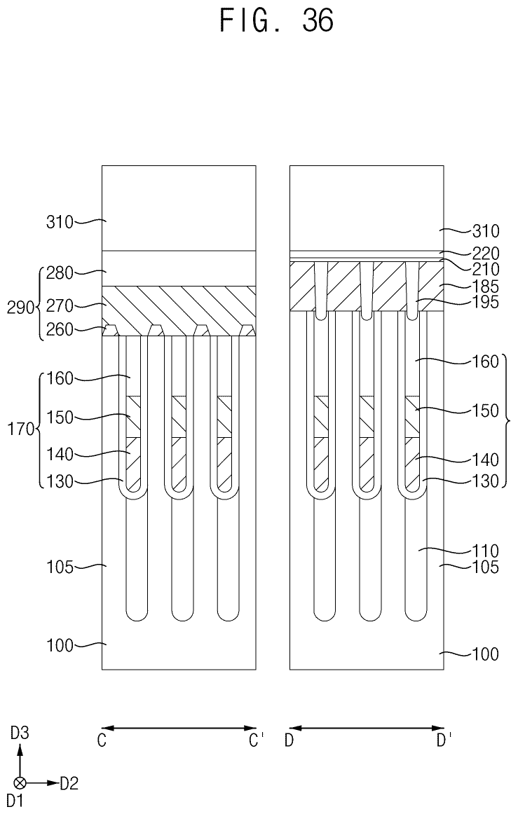

FIGS. 22 to 37 are plan views and cross-sectional views illustrating a method of manufacturing a semiconductor device according to example embodiments.

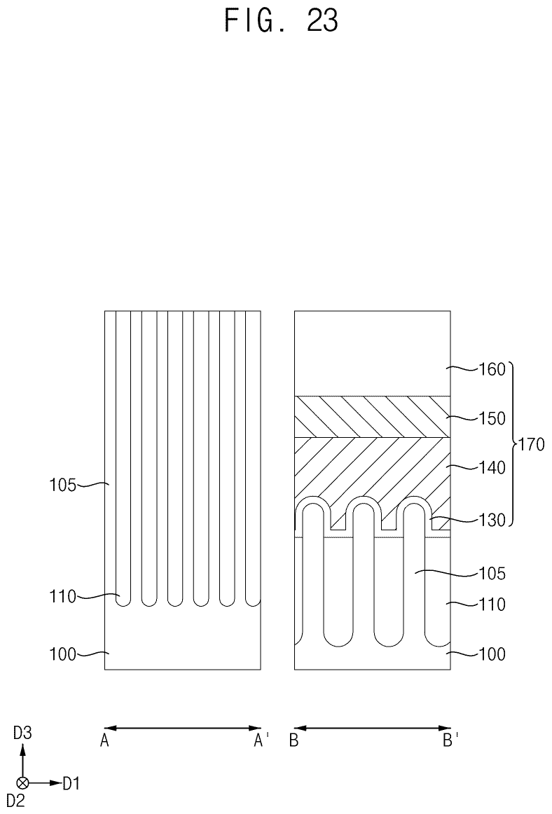

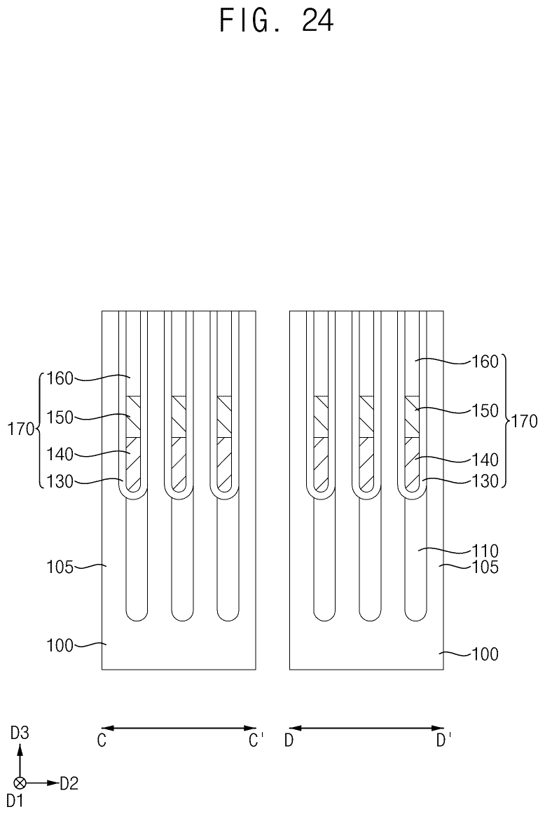

Specifically, FIGS. 22, 25, 28, 31 and 34 are the plan views, FIGS. 23, 26, 29, 32, 35 and 37 include cross-sectional views taken along lines A-A′ and B-B′ of corresponding plan views, and FIGS. 24, 27, 30, 33 and 36 include cross-sectional views taken along lines C-C′ and D-D′ of corresponding plan views.

Referring to FIGS. 22 and 24, an upper portion of the active bar 105A of the active pattern 105 and an upper portion of the isolation pattern 110 adjacent thereto in the first direction D1 may be removed to form a second recess.

A gate insulation layer may be formed on an inner sidewall of the second recess. A first conductive layer may be formed on the gate insulation layer, and an upper portion of the first conductive layer may be removed to form a first conductive pattern 140. A second conductive layer may be formed on the first conductive pattern 140 and the gate insulation layer, and an upper portion of the second conductive layer may be removed to form a second conductive pattern 150. A gate mask layer may be formed on the second conductive pattern 150 and the gate insulation layer, and a planarization process may be performed on the gate mask layer and the gate insulation layer until the upper surfaces of the first and second pad patterns 123 and 125 and an upper surface of the first fence pattern 127 are exposed to form a gate mask 160 and a gate insulation pattern 130, respectively.

The gate insulation pattern 130, the first and second conductive patterns 140 and 150 and the gate mask 160 within the second recess may together form the gate structure 170.

In example embodiments, the gate structure 170 may extend in the first direction D1 through the upper portions of the active bars 105A of the active patterns 105 included in a corresponding active pattern row, and a plurality of gate structures 170 may be spaced apart from each other in the second direction D2.

The gate structure 170 may extend in the first direction D1 through the upper portions of the active bars 105A of the active patterns 105 of the corresponding active pattern row. However, the gate structure 170 may not extend through or into end portions in the second direction D2 of the first tabs 105B (or the second tabs) of the active patterns 105 of a neighboring active pattern row, but the concept of the present disclosure is not limited thereto. That is, if the first and second tabs 105B, 105C are sufficiently large, or if the width in the second direction D2 of the gate structure 170 is sufficiently large, the gate structure 170 may extend through or into, for example, not only the upper portions of the active bars 105A of the active patterns 105 included in the corresponding active pattern row, but also the end portions in the second direction D2 of the first tabs 105B (or the second tabs) of the active patterns 105 included in the neighboring active pattern row.

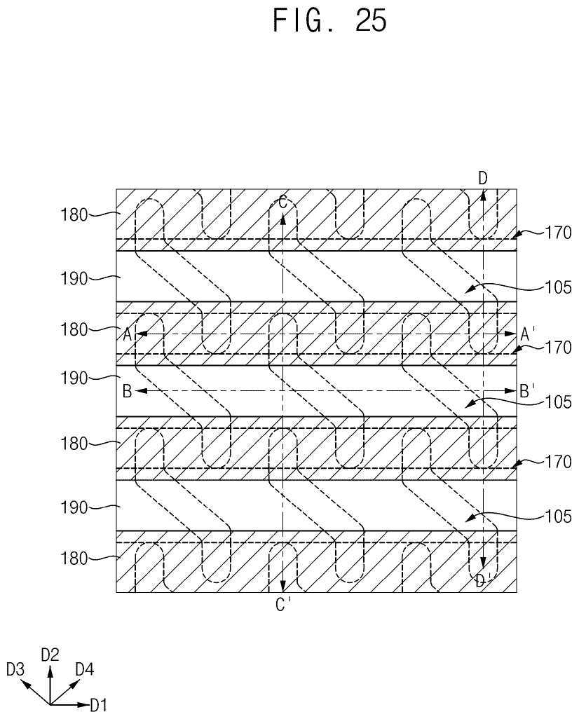

Referring to FIGS. 25 to 27, a first contact plug layer 180 may be formed on the first and second tabs 105B, 105C of the active pattern 105 and the gate structure 170.

The first contact plug layer 180 may be etched to form a first opening exposing an upper surface of the gate structure 170. Accordingly, the first contact plug layer 180 may be divided into a plurality of parts extending in the first direction D1 and spaced apart from each other in the second direction D2.

A fence layer 190 may be formed to a sufficient height within the first opening, and a planarizing process may be performed on an upper portion of the fence layer 190 until an upper surface of the first contact plug layer 180 is exposed. Accordingly, the fence layer 190 may be divided into a plurality of parts each extend in the first direction D1 between the first contact plug layers 180 adjacent to each other in the second direction D2, and spaced apart from each other in the second direction D2 by the first contact plug layers 180.

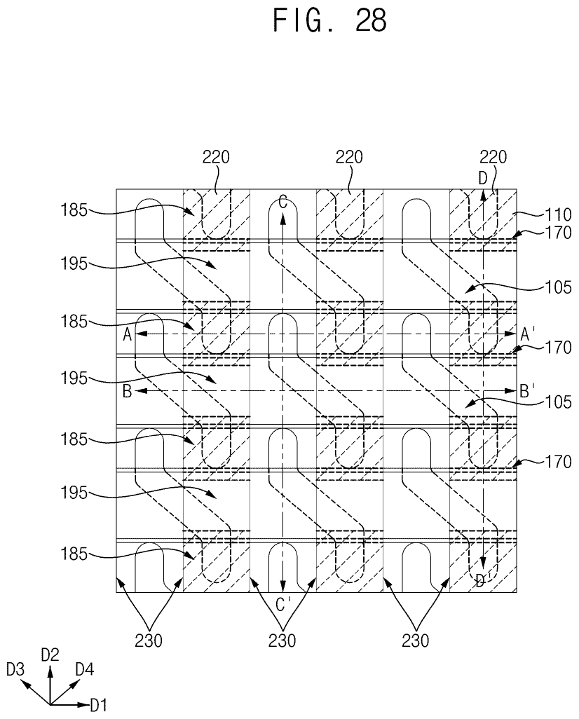

Referring to FIGS. 28 to 30, a first buffer layer 210 and a second buffer layer 220 may be sequentially formed on the first contact plug layer 180 and the fence layer 190 in the vertical direction. The first and second buffer layers 210 and 220 may together form a buffer layer structure.

An etching process may be performed to form a second opening 230 extending through or into the buffer layer structure, the first contact plug layer 180, the fence layer 190 and an upper portion of the gate structure 170.

In example embodiments, the second opening 230 may extend in the second direction D2, and a plurality of second openings 230 may be spaced apart from each other in the first direction D1. The upper surfaces of the first tabs 105B of the active patterns 105 included in the active pattern column may be exposed by the second opening 230.

The first contact plug layer 180 may be divided into a plurality of first contact plugs 185 spaced apart from each other in the first direction D1, and the fence layer 190 may be divided into a plurality of fence patterns 195 spaced apart from each other in the first direction D1 by the etching process.

In example embodiments, the first contact plugs 185 may be respectively formed on the second tabs of the active patterns 105 and spaced apart from each other in each of the first and second directions D1 and D2. The fence patterns 195 may be respectively formed between the second pad patterns 125 adjacent to each other in the second direction D2 and spaced apart from each other in each of the first and second directions D1 and D2.

Each of the first and second buffer layers 210 and 220 may be divided into a plurality of parts spaced apart from each other in the second direction D2, and may extend in the first direction D1 on the first contact plug 185 and the fence pattern 195 that are alternately and repeatedly arranged in the first direction D1.

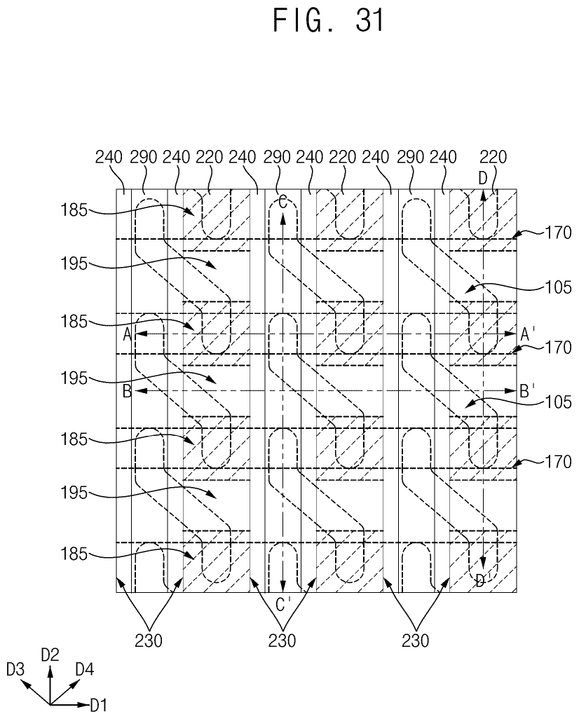

Referring to FIGS. 31 to 33, a first spacer layer may be formed, for example, conformally on a bottom and a sidewall of the second opening 230 and the upper surface of the second buffer layer 220, and a portion of the first spacer layer on the bottom of the second opening 230 and the upper surface of the second buffer layer 220 may be removed by performing an anisotropic etching process on the first spacer layer. Accordingly, the upper surfaces of the first pads of the active patterns 105 included in the active pattern column may be exposed again. The first spacer layer may be transformed into a first spacer 240 on the sidewall of the second opening 230 by the etching process.

A first metal layer may be formed on the upper surface of the first tab 105B of the active pattern 105 exposed by the second opening 230, an inner sidewall and the upper surface of the first spacer 240 and the upper surface of the second buffer layer 220, and a heat treatment process may be performed so that the first metal layer and the first tab 105B of the active pattern 105 may react with each other to form a first ohmic contact pattern 260. Unreacted portions of the first metal layer may be removed afterwards.

A third conductive layer may be formed on the first ohmic contact pattern 260 and the first spacer 240, and an upper portion of the third conductive layer may be removed to form a third conductive pattern 270. A bit line mask layer may be formed on the third conductive pattern 270 and the first spacer 240, and the bit line mask layer may be planarized until the upper surface of the second buffer layer 220 is exposed to form a bit line mask 280.

The first ohmic contact pattern 260, the third conductive pattern 270 and the bit line mask 280 may together form the bit line 290.

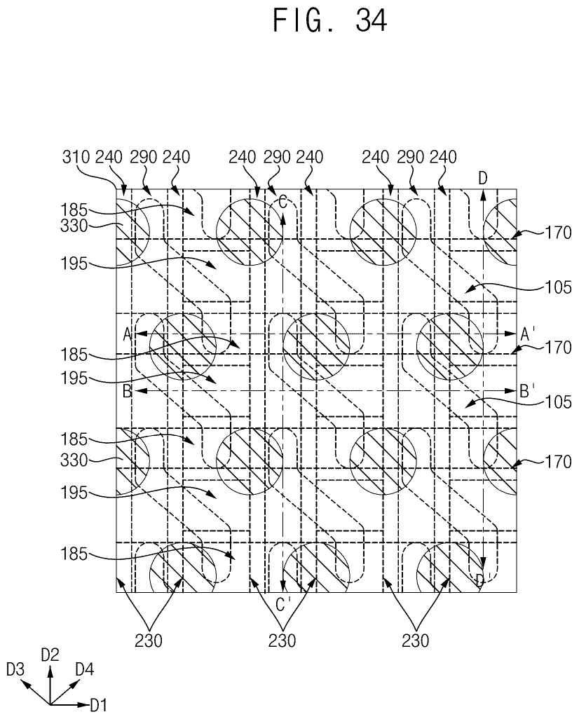

Referring to FIGS. 34 to 36, a second mold layer 310 may be formed on the second buffer layer 220 and the bit line 290, and a third opening 320 extending through or into the second mold layer 310 may be formed to at least partially expose an upper surface of the first contact plug 185.

A second contact plug layer may be formed to a sufficient height to fill or be in the third opening 320, and a planarization process may be performed on an upper portion of the second contact plug layer until an upper surface of the second mold layer 310 is exposed. Accordingly, the second contact plug layer may be divided into a plurality of second contact plugs 330.

Referring to FIGS. 37, an upper portion of the second contact plug 330 may be removed. Accordingly, an upper portion of the third opening 320 may be formed again. A second spacer layer may be formed on an upper surface of the second contact plug 330 exposed by the third opening 320 and an inner sidewall and the upper surface of the second mold layer 310, and an anisotropic etching process may be performed on the second spacer layer to form a second spacer 340. The upper surface of the second contact plug 330 may be exposed again.

A second ohmic contact pattern 350 may be formed on the exposed upper surface of the second contact plug 330. In example embodiments, the second ohmic contact pattern 350 may be formed by forming a second metal layer on the exposed upper surface of the second contact plug 330 and the second mold layer 310, performing a heat treatment thereon, and removing an unreacted portion of the second metal layer.

A third contact plug 360 may be formed on the second ohmic contact pattern 350 to fill the third opening 320. In example embodiments, the third contact plug 360 may be formed by forming a third contact plug layer to a sufficient height to fill or be in the third opening 320 on the second ohmic contact pattern 350, and performing a planarization process on an upper portion of the third contact layer.

The second contact plug 330, the second ohmic contact pattern 350 and the third contact plug 360 may together form a contact plug structure.

In example embodiments, a plurality of contact plug structures may be spaced apart from each other in each of the first and second directions D1 and D2, and may be arranged in a honeycomb pattern in a plan view. Each of the contact plug structures may have shape of, for example, a circle, an ellipse, a polygon, etc., in a plan view.

Referring to FIGS. 19 to 21 again, a third mold layer may be formed on the second mold layer 310 and the third contact plug 360.

An etching process may be performed on the third mold layer to form a fourth opening exposing an upper surface of the third contact plug 360.

As the contact plug structures are arranged in a honeycomb pattern in a plan view, a plurality of fourth openings exposing the upper surfaces of the contact plug structures may also be arranged in a honeycomb pattern in a plan view.

A lower electrode 400 having a shape of a pillar may be formed in the fourth opening, the third mold layer may be removed, a dielectric layer 410 and an upper electrode 420 may be sequentially formed on the lower electrode 400 and the second mold layer 310. The lower electrode 400, the dielectric layer 410 and upper electrode 420 sequentially stacked may together form a capacitor 430. Alternatively, the lower electrode 400 may be formed to have a shape of a cylinder within the fourth opening.

Thereafter, manufacturing of the semiconductor device may be completed by additionally forming upper wirings on the capacitor 430.

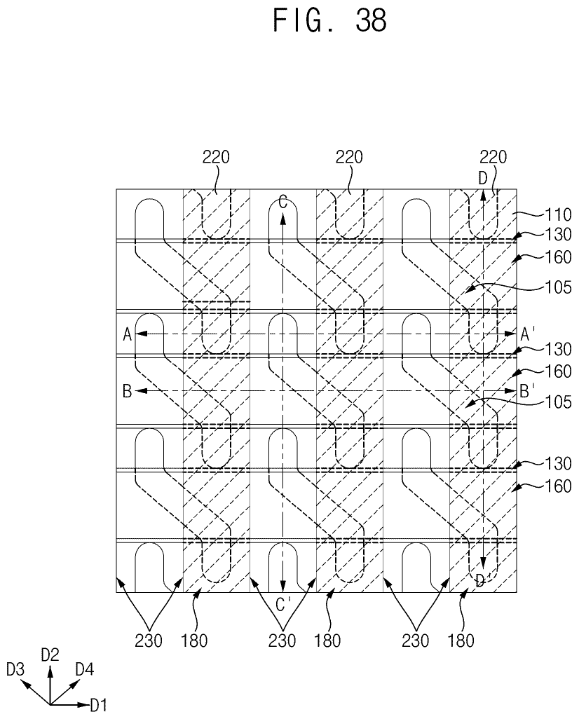

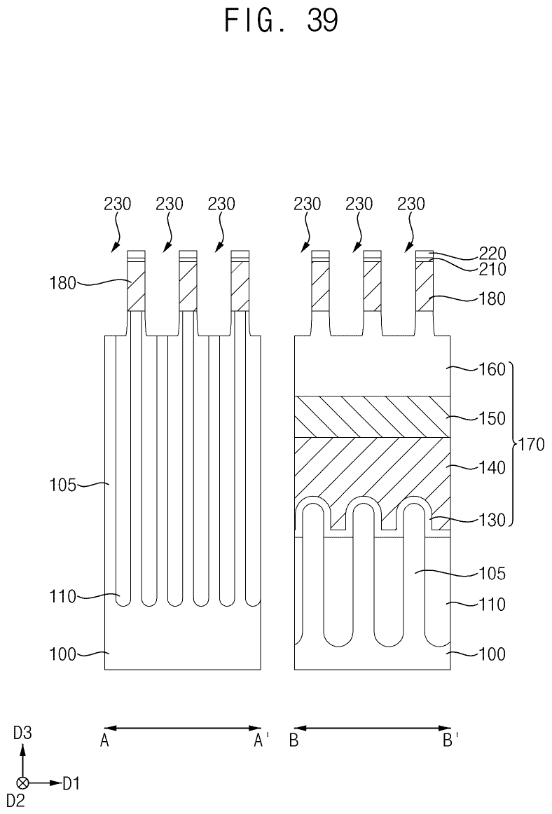

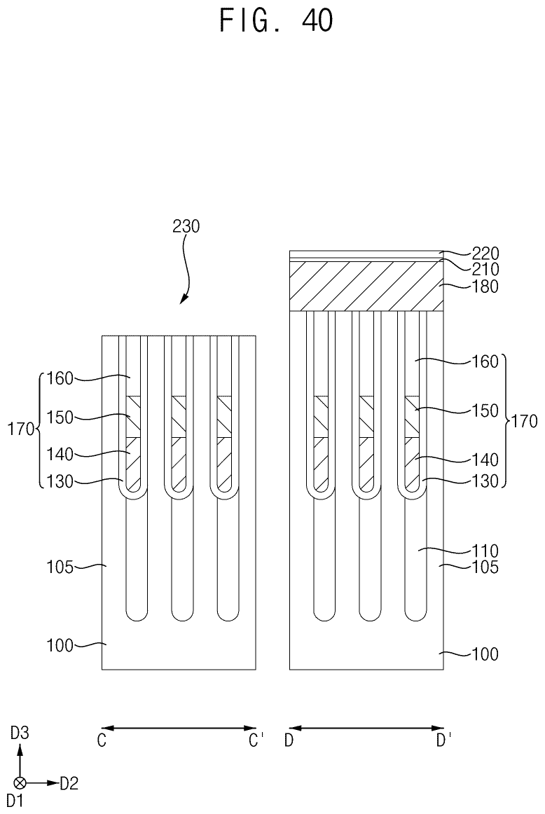

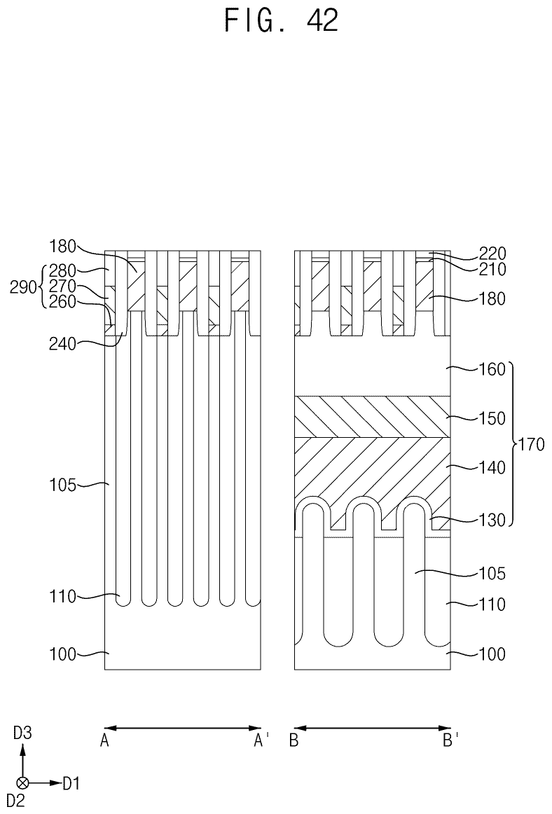

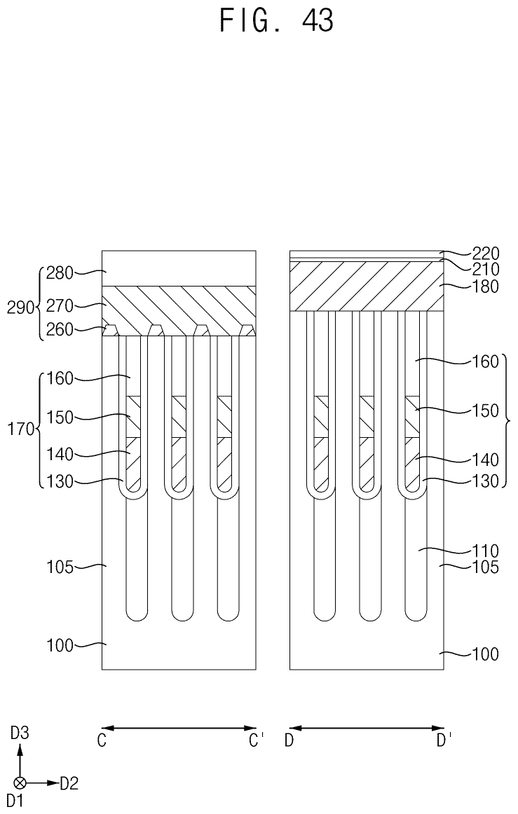

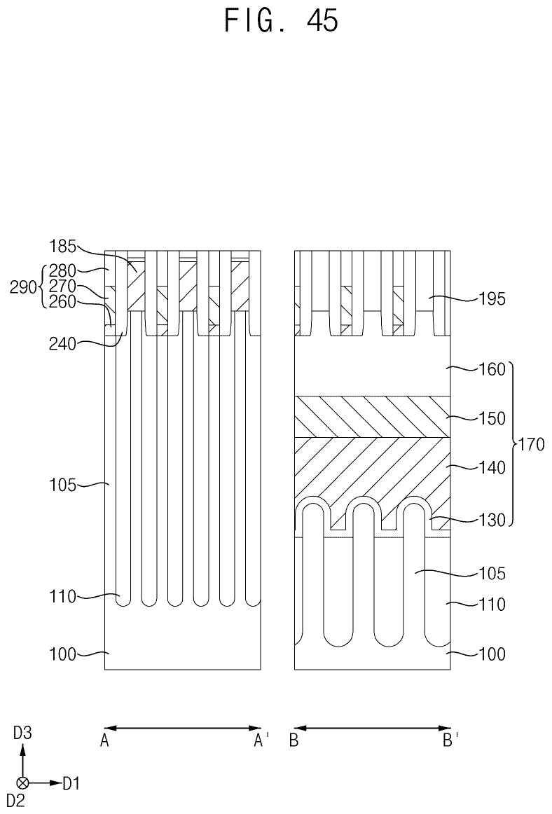

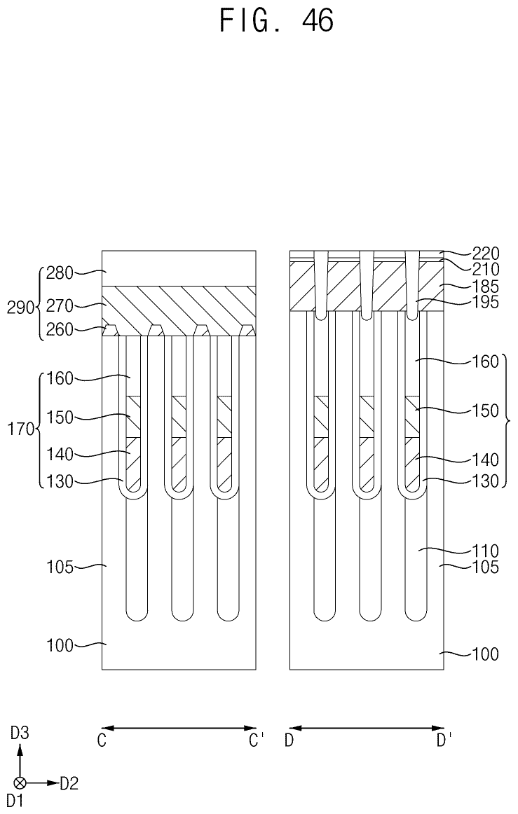

FIGS. 38 to 46 are plan views and cross-sectional views illustrating a method of forming a semiconductor device in accordance with example embodiments. Specifically, FIGS. 38, 41 and 44 are the plan view, FIGS. 39, 42 and 45 include cross-sectional views taken along lines A-A′ and B-B′ of corresponding plan views, and FIGS. 40, 43 and 46 include cross-sectional views taken along lines C-C′ and D-D′ of corresponding plan views.

This method may include processes substantially the same as or similar to those illustrated with reference to FIGS. 19 to 37, except for processes of forming of the first contact plug 185, the fence pattern 195 and the bit line 290 illustrated with reference to FIGS. 25 to 33, and thus repeated explanations thereof are omitted herein.

Referring to FIGS. 38 to 40, after performing processes substantially the same as or similar to those illustrated with reference to FIGS. 22 to 24, the first contact plug layer 180 and the buffer layer structure may be formed on the active pattern 105 and the isolation pattern 110 in the vertical direction. The buffer layer structure may include the first buffer layer 210 and the second buffer layer 220 sequentially stacked in the vertical direction.

An etching process may be performed on the buffer layer structure and the first contact plug layer 180 to form the second opening 230 exposing the upper surfaces of the first tabs 105B of the active patterns 105 of the active pattern column.

The first contact plug layer 180 and the buffer layer structure may be divided into a plurality of parts each extending in the second direction D2 and spaced apart from each other in the first direction D1 by the etching process.

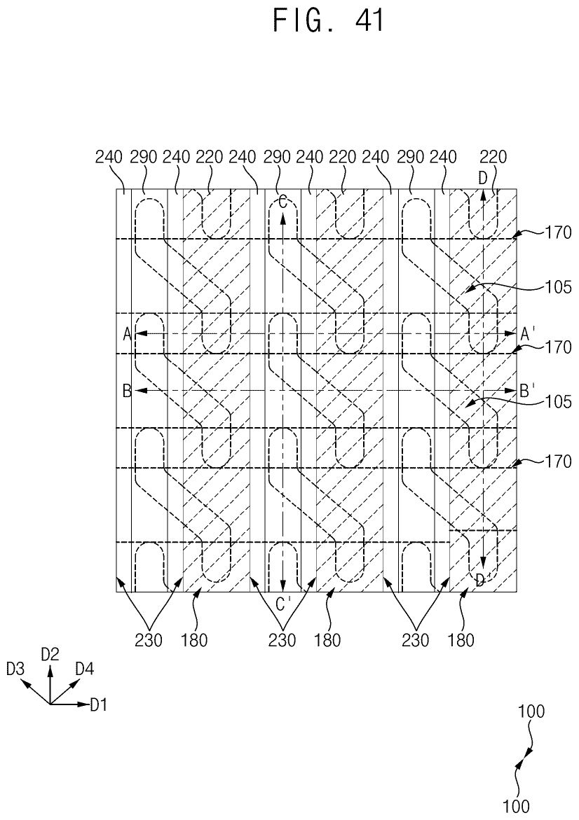

Referring to FIGS. 41 to 43, the first spacer 240 may be formed on the sidewall of the second opening 230. Thereafter, the bit line 290 including the first ohmic contact pattern 260, the third conductive pattern 270 and the bit line mask 280 sequentially stacked on the bottom of the second opening 230 may be formed. Hereinafter, the bit line 290 and the first spacers 240 formed on the opposite sidewalls of the bit line 290 may be referred to as the bit line structure together.

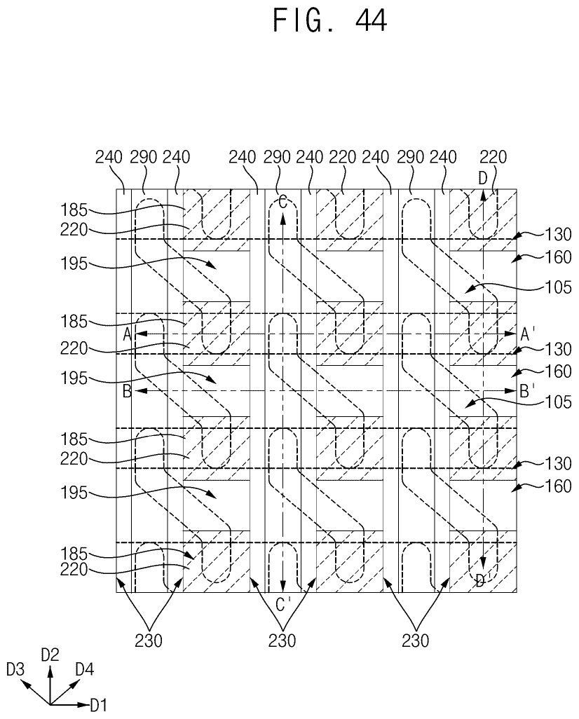

Referring to FIGS. 44 to 46, an etching process may be performed to remove portions of the first contact plug layer 180 and the buffer layer structure overlapping the gate structure 170 in the vertical direction to form a fifth opening exposing the upper surface of the gate structure 170.

By the etching process, a plurality of fifth openings spaced apart from each other in the second direction D2 between the bit line structures adjacent to each other in the first direction D1 may be formed. Accordingly, the first contact plug layer 180 may be divided into the plurality of the first contact plugs 185 spaced apart from each other in the second direction D2.

The fence pattern 195 may be formed within the fifth opening. The fence pattern 195 may be formed by, for example, forming the fence layer 190 to a sufficient height to fill or be in the fifth opening, and performing planarization process on the upper portion of the fence layer 190 until the upper surfaces of the second buffer layer 220, the first spacer 240 and the bit line 290 are exposed.

Thereafter, manufacturing of the semiconductor device may be completed by performing processes substantially the same as or similar to the processes illustrated with reference to FIGS. 34 to 37 and FIGS. 19 to 21.

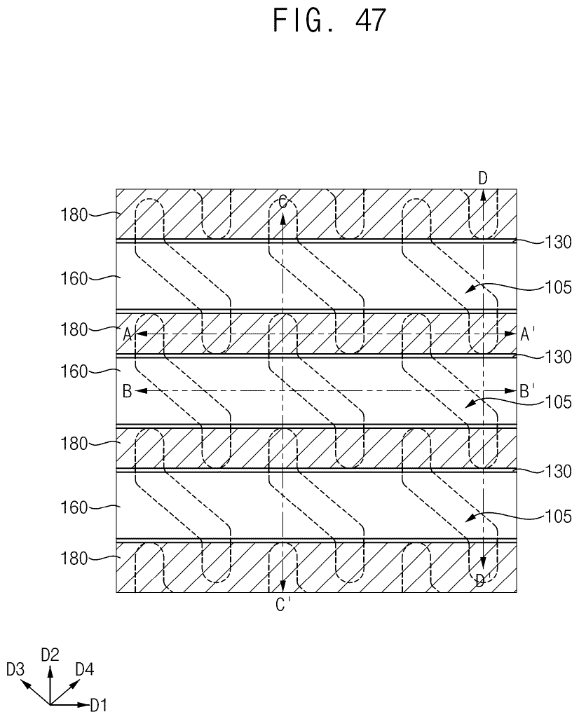

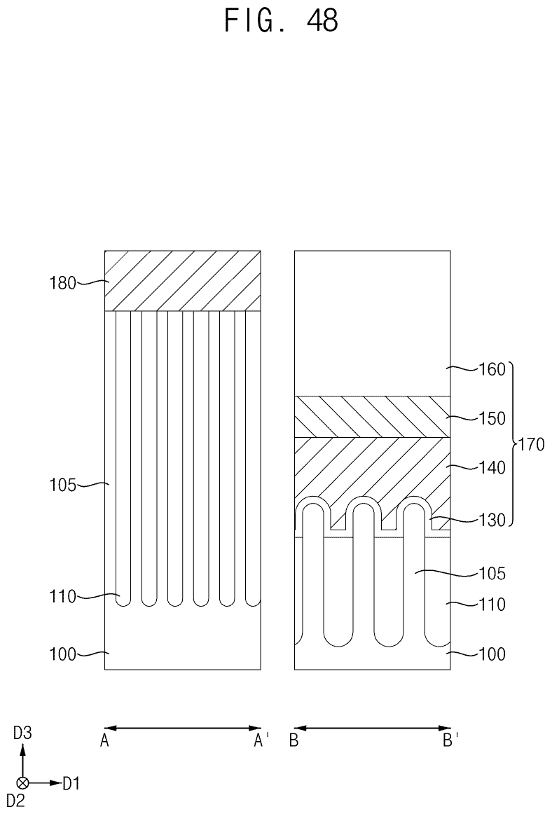

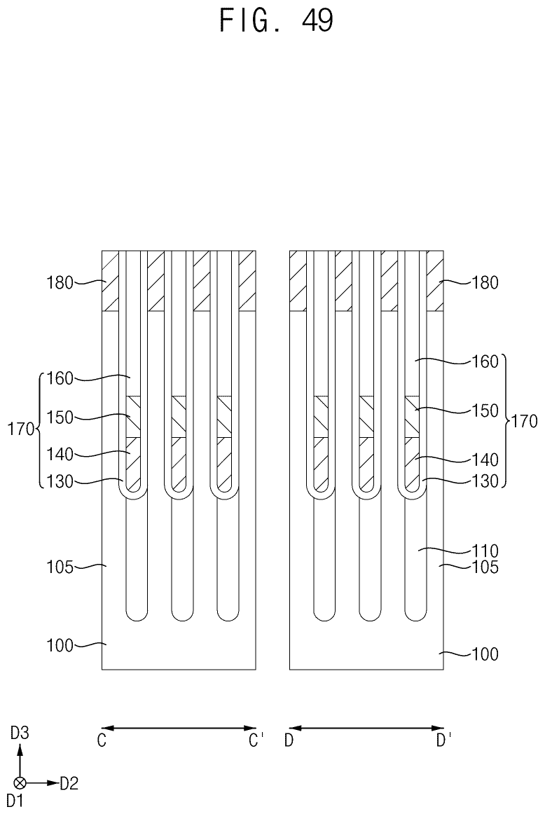

FIGS. 47 to 49 are a plan view and cross-sectional views illustrating a method of forming a semiconductor device in accordance with example embodiments. Specifically, FIG. 47 is the plan view, FIG. 48 includes cross-sectional views taken along lines A-A′ and B-B′ of FIG. 47, and FIG. 49 includes cross-sectional views taken along lines C-C′ and D-D′ of FIG. 47.

This method may include processes substantially the same as or similar to those illustrated with reference to FIGS. 19 to 37, except for not forming the fence pattern 195, and process sequence for forming of the first contact plug 185 and the gate structure 170, and thus repeated explanations thereof are omitted herein.

Referring to FIGS. 47 to 49, unlike the processes illustrated with reference to FIGS. 22 to 27, the first contact plug layer 180 may be formed on the active pattern 105 and the isolation pattern 110.

The gate structure 170 extending through or into the first contact plug layer 180, the upper portion of the active bars 105A of the active patterns 105 included in the active pattern row and the upper portion of the isolation pattern 110 adjacent thereto may be formed. The first contact plug layer 180 may be divided into a plurality of parts each extending in the first direction D1 and spaced apart from each other in the second direction D2.

Thereafter, manufacturing of the semiconductor device may be completed by performing processes substantially the same as or similar to the processes illustrated with reference to FIGS. 28 to 37 and FIGS. 19 to 21.

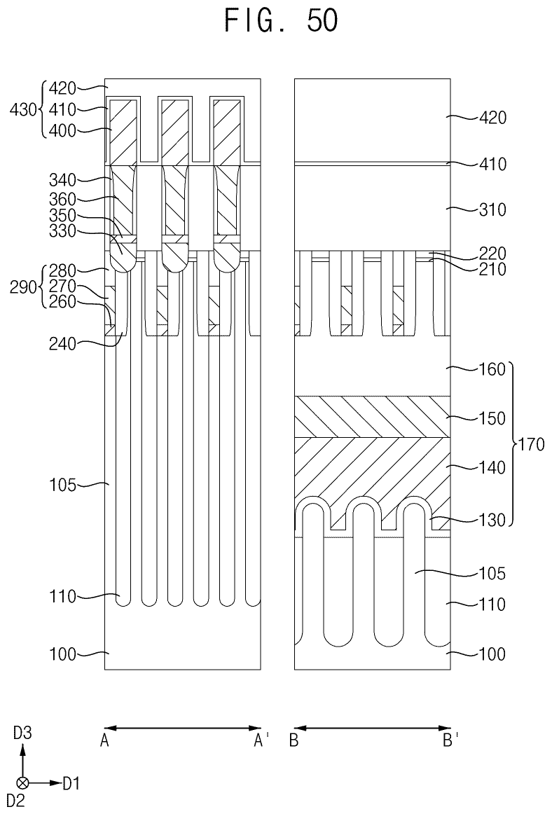

FIG. 50 is a cross-sectional view illustrating a semiconductor device in accordance with example embodiments. The semiconductor device may be substantially the same as or similar that of FIGS. 19 to 21, except for not including the first contact plug 185 and the fence pattern 195 and the location of the contact plug structure, and thus, repeated explanations are omitted herein.

Referring to FIG. 50, the bit line structure may be formed to extend through or into the buffer layer structure, the upper portion of the first tabs 105B of the active patterns 105 included in the active pattern column, the upper portion of the isolation pattern 110 and the upper portion of the gate structure 170.

The contact plug structure may be formed within the third opening 320 extending through or into the second mold layer 310, the buffer layer structure, the upper portion of the bit line structure and the upper portion of the second tab 105C of the active pattern 105. Accordingly, the second contact plug 330 of the contact plug structure may directly contact the second tab 105C of the active pattern 105. The contact plug structures may be arranged in a honeycomb pattern in a plan view.

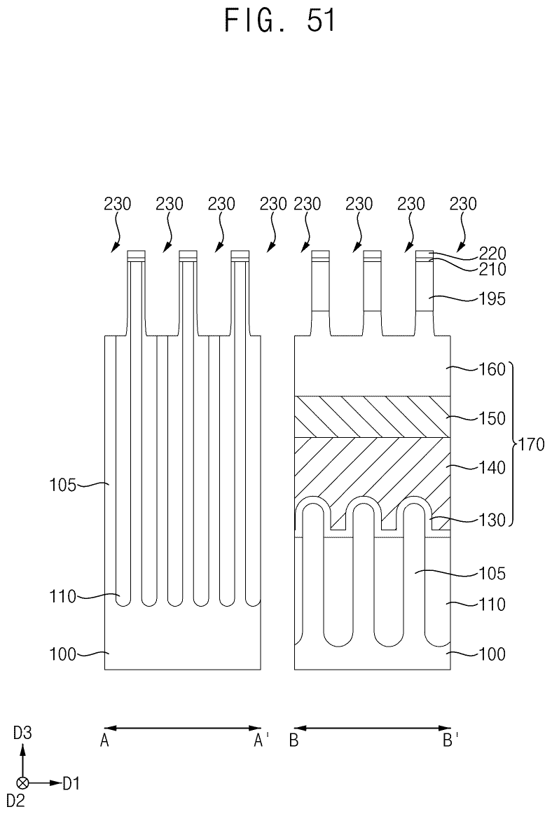

FIG. 51 is a cross-sectional view illustrating a method of forming the semiconductor device illustrated with reference to FIG. 50. Specifically, FIG. 51 includes cross-sectional views taken along lines A-A′ and B-B′ of a corresponding plan view.

This method may include processes substantially the same as or similar to those illustrated with reference to FIGS. 19 to 37, except for not performing the processes illustrated with reference to FIGS. 25 to 27, and thus repeated explanations thereof are omitted herein.

Referring to FIG. 51, unlike the processes illustrated with reference to FIGS. 28 to 30, the buffer layer structure may be formed on the active pattern 105, the isolation pattern 110 and the gate structure 170.

An etching process may be performed to form the second opening 230 that extends through or into the buffer layer structure, the upper portion of the first tab 105B of the active pattern 105, the upper portion of the isolation pattern 110 and the upper portion of the gate structure 170 to expose the upper surfaces of the first tabs 105B of the active patterns 105 included in the active pattern column.

Thereafter, manufacturing of the semiconductor device may be completed by performing processes substantially the same as or similar to the processes illustrated with reference to FIGS. 28 to 37 and FIGS. 19 to 21.

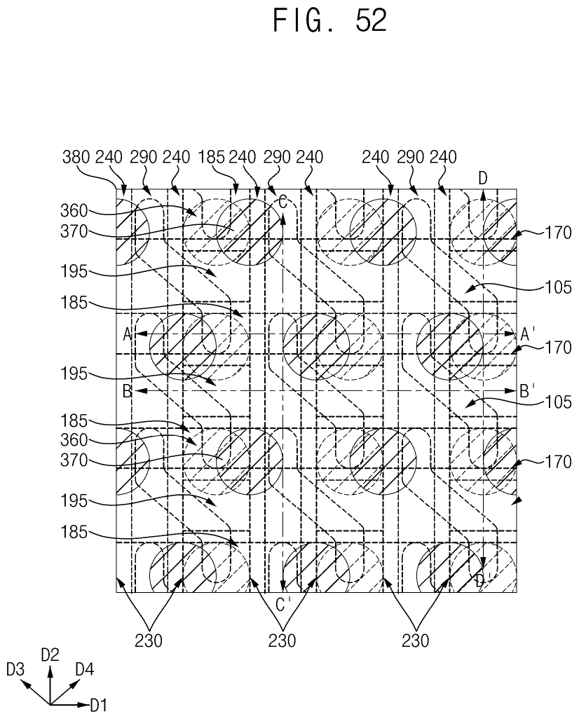

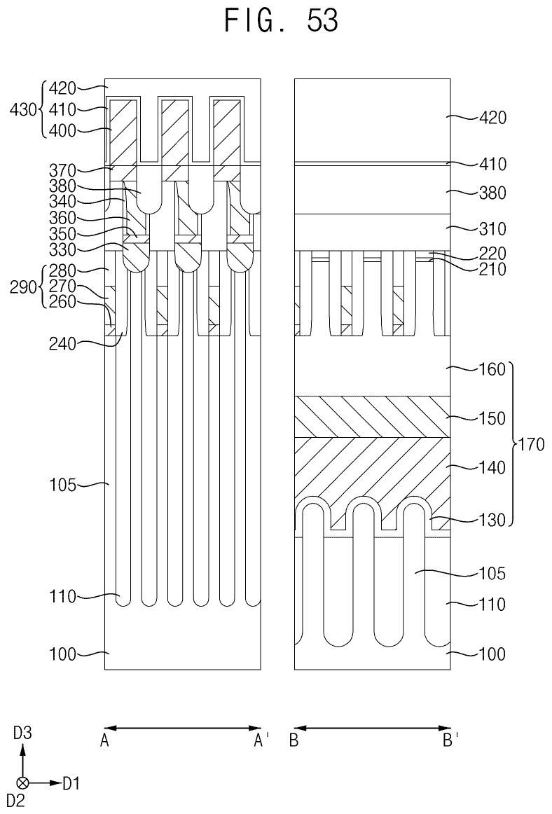

FIGS. 52 and 53 are a plan view and a cross-sectional view illustrating a semiconductor device in accordance with example embodiments. The semiconductor device may be substantially the same as or similar that of FIG. 50, except for further including a fourth contact plug 370 and an insulation pattern 380 and the arrangement of the contact plug structure, and thus, repeated explanations are omitted herein.

The capacitor 430 is not illustrated in FIG. 52 to avoid complexity.

Referring to FIGS. 52 and 53, the contact plug structures may be arranged, for example, in a lattice pattern in a plan view.

The fourth contact plug 370 may be disposed on the contact plug structure, and, for example, may serve as a landing pad. In example embodiments, a plurality of fourth contact plugs 370 may be spaced apart from each other in each of the first and second directions D1 and D2. The fourth contact plug 370 may be arranged to be offset from a corresponding contact plug structure in the first direction D1, and thus, the fourth contact plug 370 may be arranged, for example, in a honeycomb pattern in a plan view.

In example embodiments, the fourth contact plug 370 may include, for example, a metal pattern containing a metal and a barrier pattern that may cover a lower surface of the metal pattern and contain, for example, a metal nitride.

The insulation pattern 380 may fill or be in a space between the fourth contact plugs 370. The insulation pattern 380 may include, for example, a low dielectric material such as silicon oxide, silicon oxycarbide, silicon nitride, silicon oxycarbonitride, etc.

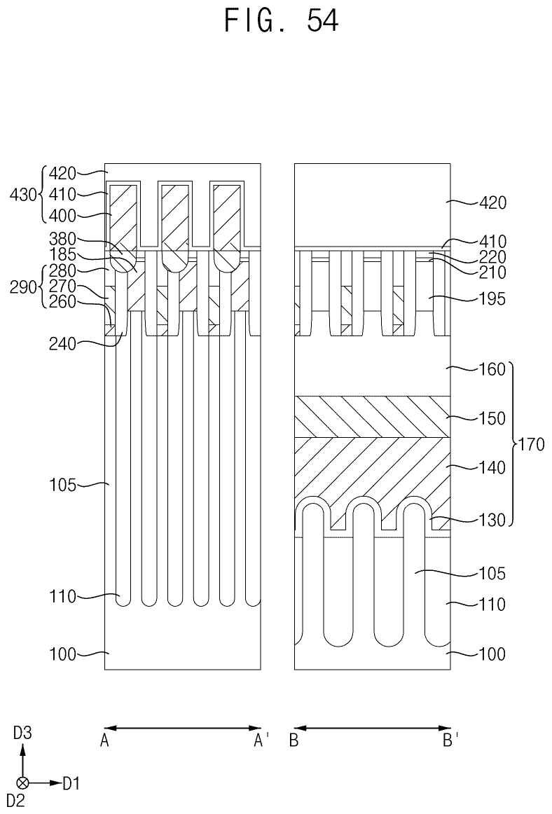

FIG. 54 is a cross-sectional view illustrating a semiconductor device in accordance with example embodiments. The semiconductor device may be substantially the same as or similar that of FIG. 19 to FIGS. 22, except for not including the contact plug structure and the second spacer 340 and further including a fourth contact plug 370, and thus, repeated explanations are omitted herein.

Referring to FIG. 54, the fourth contact plug 370 may extend through or into the buffer layer structure and the upper portion of the bit line structure to directly contact the first contact plug 185. In example embodiments, the fourth contact plug 370 may be arranged in a honeycomb pattern in a plan view.

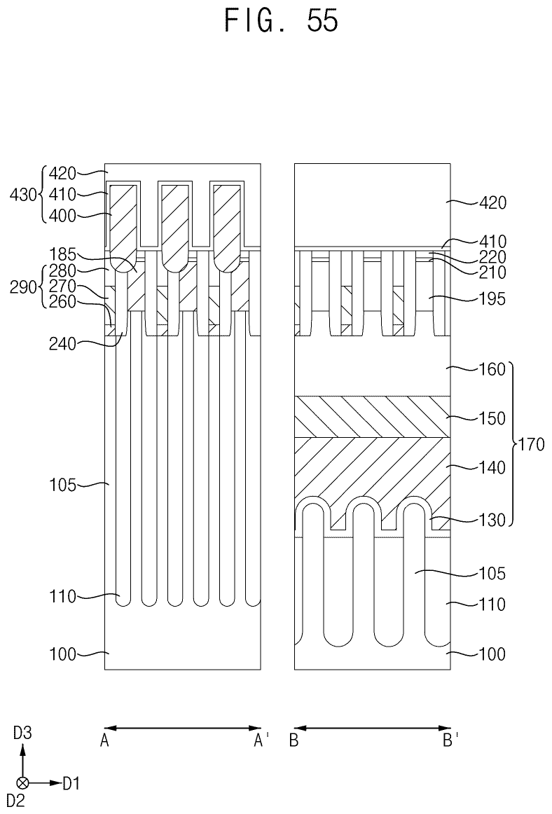

FIG. 55 is a cross-sectional view illustrating a semiconductor device in accordance with example embodiments. The semiconductor device may be substantially the same as or similar that of FIG. 19 to FIGS. 22, except for not including second mold layer 310, the contact plug structure and the second spacer 340 and the shape of the lower electrode 400, and thus, repeated explanations are omitted herein.

Referring to FIG. 55, the lower electrode 400 may extend through or into the buffer layer structure and the upper portion of the bit line structure to directly contact the first contact plug 185.

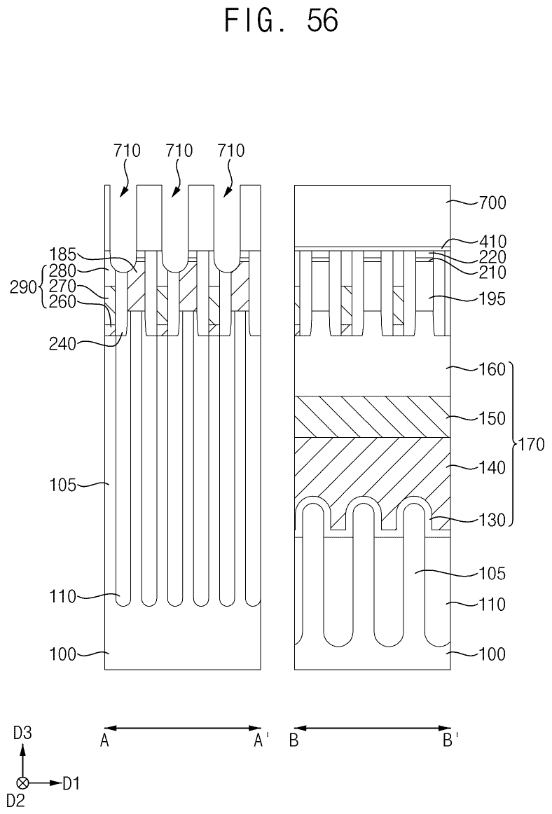

FIG. 56 is a cross-sectional view illustrating a method of forming the semiconductor device illustrated with reference to FIG. 55. Specifically, FIG. 56 is a cross-sectional view taken along line A-A′ of a corresponding plan view.

This method may include processes substantially the same as or similar to those illustrated with reference to FIGS. 19 to 37, except for not performing the processes illustrated with reference to FIGS. 34 to 37, and thus repeated explanations thereof are omitted herein.

Referring to FIG. 56, the processes substantially the same as or similar to those illustrated with reference to FIGS. 23 to 33 may be performed. Thereafter, unlike the processes illustrated with reference to FIGS. 19 to 21, a fourth mold layer 700 may be formed on the second buffer layer 220 and the bit line structure.

Thereafter, a sixth opening 710 extending through or into the fourth mold layer 700, the buffer layer structure, the upper portion of the bit line structure and the upper portion of the first contact plug 185 may be formed to expose the upper surface of the first contact plug 185, and the lower electrode 400 may be formed within the sixth opening 710. Accordingly, the lower electrode 400 may be formed to directly contact the first contact plug 185.

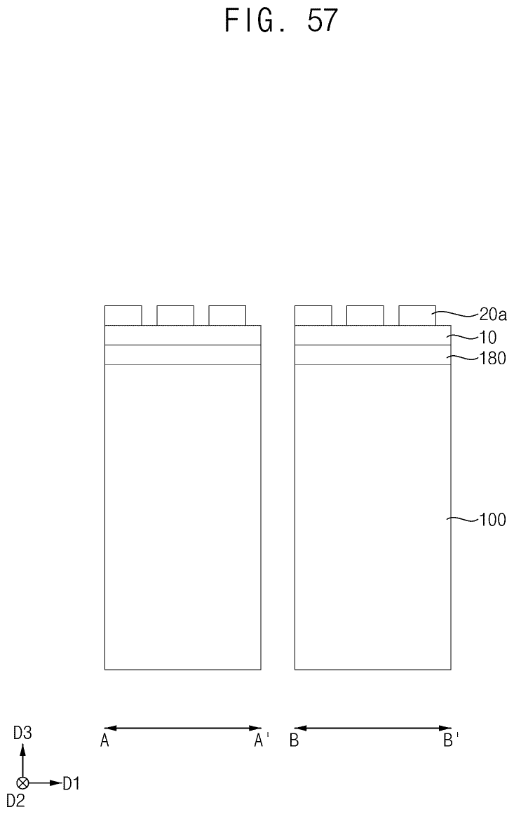

FIG. 57 is a cross-sectional view illustrating a method of forming a semiconductor device including the active pattern 105 in accordance with example embodiments. Specifically, FIG. 57 is a cross-sectional view taken along line A-A′ of a corresponding plan view.

This method may include processes substantially the same as or similar to those illustrated with reference to FIGS. 1 to 9 and FIGS. 19 to 37, except that the active pattern 105 and the first contact plug 185 may be simultaneously formed, and thus repeated explanations thereof are omitted herein.

Referring to FIG. 57, unlike the processes of the active pattern 105 illustrated with reference to FIGS. 4 and 5, the first contact plug layer 180 may formed on the substrate 100 first, and the hard mask layer 10 may be formed on the first contact plug layer 180 after. Thereafter, manufacturing of the active pattern 105 and the first contact plug 185 may be completed by performing processes substantially the same or similar to the processes illustrated with reference to FIGS. 6 to 9 and FIGS. 1 to 3.

In example embodiments, the upper surface of the first contact plug 185 may have substantially the same shape as the upper surface of the second tab 105C of a corresponding active pattern 105 in plan view.

Thereafter, manufacturing of the semiconductor device may be completed by performing processes substantially the same as or similar to the processes illustrated with reference to FIGS. 23 to 37 and FIGS. 19 to 21.

While example embodiments have been particularly shown and described, it will be understood by one of ordinary skill in the art that variations in form and detail may be made therein without departing from the spirit and scope of the claims.

What is claimed is:

1. A semiconductor device comprising:
an active pattern on a substrate, the active pattern comprising a first tab, a second tab, and an active bar between the first tab and the second tab;
a gate structure extending into the active bar of the active pattern in a first direction that is substantially parallel to an upper surface of the substrate;
a bit line structure on the first tab of the active pattern and extending in a second direction that is substantially parallel to the upper surface of the substrate and orthogonal to the first direction;
a contact plug structure on the second tab of the active pattern; and
a capacitor on the contact plug structure,
wherein the active bar of the active pattern extends in a third direction,
wherein the first tab and the second tab of the active pattern are respectively on a first end of the active bar and a second end of the active bar that is opposite to the first end in the third direction and extend from the active bar in the second direction,
wherein the third direction is substantially parallel to the upper surface of the substrate, defines an obtuse angle with respect to the first direction, and defines an acute angle with respect to the second direction.

2. The semiconductor device of claim 1, wherein an upper surface of each of the first tab and the second tab has a shape of a semi-oval in a plan view.

3. The semiconductor device of claim 1, wherein an upper surface of each of the first tab and the second tab has a shape of a rectangle in a plan view, the rectangle comprising a first pair of sides facing each other in the first direction and a second pair of sides facing each other in the second direction.

4. The semiconductor device of claim 3, wherein vertices of the rectangle are rounded.

5. The semiconductor device of claim 1, wherein an upper surface of each of the first tab and the second tab has a shape of a rhombus in a plan view, the rhombus comprising a first pair of sides facing each other in the third direction and a second pair of sides facing each other in a fourth direction that is substantially parallel to the upper surface of the substrate, defines a first acute angle with respect to the first direction, defines a second acute angle with respect to the second direction, and is substantially perpendicular to the third direction.

6. The semiconductor device of claim 1, wherein an upper surface of each of the first tab and the second tab has a shape of a pentagon in a plan view, the pentagon comprising two angled vertices.

7. The semiconductor device of claim 1, wherein a first distance between a center line of the active bar and a first side of the first tab in the first direction and a second distance between the center line of the active bar and a second side of the second tab in the first direction are different from each other, the center line extending through a center of gravity of the active bar in the second direction.

8. The semiconductor device of claim 1, wherein a first distance between a center line of the active bar and a first side of the first tab in the second direction and a second distance between the center line and a second side of the second tab in the second direction are different from each other, the center line extending through a center of gravity of the active bar in the first direction.

9. The semiconductor device of claim 1, wherein a width of the active bar in a fourth direction increases from a center portion of the active bar towards each of the first end of the active bar and the second end of the active bar, wherein the fourth direction is substantially parallel to the upper surface of the substrate, defines a first acute angle with respect to the first direction, defines a second acute angle with respect to the second direction, and is substantially perpendicular to the third direction.

10. The semiconductor device of claim 1, wherein a width of the active bar in a fourth direction decreases from a center portion of the active bar towards each of first end of the active bar and the second end of the active bar, wherein the fourth direction is substantially parallel to the upper surface of the substrate, defines a first acute angle with respect to the first direction, defines a second acute angle with respect to the second direction, and is substantially perpendicular to the third direction.

11. The semiconductor device of claim 1, wherein a first width of a first interface of the active bar and the first tab and a second width of a second interface of the active bar and the second tab are less than a third width of the active bar.

12. The semiconductor device of claim 1, wherein a first width of a first interface of the active bar and the first tab and a second width of a second interface of the active bar and the second tab are greater than a third width of the active bar.

13. The semiconductor device of claim 1, wherein the contact plug structure further comprises a first contact plug directly contacting the second tab of the active pattern, and wherein an upper surface of the first contact plug and an upper surface of the second tab of the active pattern have substantially a same shape in a plan view.

14. A semiconductor device comprising:
a plurality of active patterns that are on a substrate and spaced apart in a first direction and a second direction that is orthogonal to the first direction,
wherein each active pattern of the plurality of active patterns comprises a first tab, a second tab spaced apart from the first tab in a third direction, and an active bar that is between the first tab and the second tab and extends in the third direction,
wherein the third direction is substantially parallel to an upper surface of the substrate, defines an obtuse angle with respect to the first direction, and defines an acute angle with respect to the second direction, and
wherein the first tab and the second tab of each of the plurality of active patterns extend in the second direction from the active bar.

15. The semiconductor device of claim 14, wherein:
a first set of the plurality of active patterns that are spaced apart in the first direction defines a first active pattern row among a plurality of active pattern rows that are spaced apart from each other in the second direction,
a second set of the plurality of active patterns that are spaced apart in the first direction defines a second active pattern row among the plurality of active pattern rows is adjacent to the first set of the plurality of active patterns, and
the first tab of each of the first set of the plurality of active patterns and the second tab of each of the second set of the plurality of active patterns are alternately stacked in the first direction.

16. The semiconductor device of claim 14, wherein an upper surface of each of the first tab and the second tab of the plurality of active patterns has a shape of a semi-oval in a plan view.

17. The semiconductor device of claim 14, wherein an upper surface of each of the first tab and the second tab of the plurality of active patterns has a shape of a rectangle in a plan view, the rectangle comprising a first pair of sides facing each other in the first direction and a second pair of sides facing each other in the second direction.

18. The semiconductor device of claim 14, wherein an upper surface of each of the first tab and the second tab of the plurality of active patterns has a shape of a rhombus in a plan view, the rhombus comprising a first pair of sides facing each other in the third direction and a second pair of sides facing each other in a fourth direction that is substantially parallel to the upper surface of the substrate, defines a first acute angle with respect to the first direction, and defines a second acute angle with respect to the second direction, and is substantially perpendicular to the third direction.

19. The semiconductor device of claim 14, wherein an upper surface of each of the first tab and the second tab of the plurality of active patterns has a shape of a pentagon in a plan view, the pentagon comprising two angled vertices.

20. A semiconductor device comprising:
a plurality of active patterns that are on a substrate and spaced apart in a first direction and a second direction that is orthogonal to the first direction, wherein:
each active pattern of the plurality of active patterns comprises a first tab, a second tab spaced apart from the first tab in a third direction, and an active bar that is between the first tab and the second tab and extends in the third direction,
the third direction is substantially parallel to an upper surface of the substrate, defines an obtuse angle with respect to the first direction, and defines an acute angle with respect to the second direction,
the first tab and the second tab of each of the plurality of active patterns extend in the second direction from the active bar,
a first set of the plurality of active patterns are spaced apart in the first direction, and
a second set of the plurality of active patterns are spaced apart in the second direction,
a gate structure extending into the active bars of the first set of the plurality of active patterns;
a bit line structure extending into the first tabs of the second set of the plurality of active patterns;
contact plug structures that are respectively on the second tabs of the plurality of active patterns; and
capacitors that are respectively on the contact plug structures.
